(19) United States
(12) Patent Application Publication
(10) Pub. No.: US 2012/0086331 A1
(43) Pub. Date: Apr. 12, 2012

(54) WHITE LIGHT EMITTING ORGANIC ELECTROLUMINESCENT ELEMENT

(75) Inventors: Yasunobu Kobayashi, Tokyo (JP); Kunimasa Hiyama, Tokyo (JP)

(73) Assignee: KONICA MINOLTA HOLDINGS, INC., Tokyo (JP)

(21) Appl. No.: 13/378,813

(22) PCT Filed: Jun. 17, 2010
(86) PCT No.: PCT/JP2010/060272

§ 371 Date: Dec. 16, 2011

Related U.S. Application Data
(66) Substitute for application No. PCT/JP2010/060272, filed on Jun. 17, 2010.

(30) Foreign Application Priority Data
Jun. 25, 2009 (JP) 2009-150883

(51) Int. Cl. H05B 33/14

(52) U.S. Cl. 313/504

(57) ABSTRACT

Provided is a white light-emitting organic EL element wherein a flexible plastic substrate is used, but the resistance to negative effects caused by the flexibility is excellent; a removal of a light emitting layer interface caused by folding the element and a contact failure do not tend to occur, and the drive voltage can be reduced. The white light-emitting organic EL element is formed by providing at least two layers, i.e., a light emitting layer (A) and a light emitting layer (B) on the plastic substrate. The white light-emitting organic EL element is characterized in that the light emitting layer (A) contains more than three kinds of luminescent dopants including a red luminescent dopant, a green luminescent dopant, and a blue luminescent dopant; the light emitting layer (B) contains the blue luminescent dopant; the light emitting layer (A) and the light emitting layer (B) are adjacent to each other, the light emitting layer (A) is formed on the side adjacent to the positive electrode, and the light emitting layer (B) is formed on the side adjacent to the negative electrode; and a mixed area is provided between the light emitting layer (A) and the light emitting layer (B).

### TECHNICAL FIELD

The present invention relates to a white light emitting organic electroluminescent element, and more in detail, relates to a white light emitting organic electroluminescent element employing a flexible resin substrate.

### TECHNICAL BACKGROUND

Examples of emission type electronic display devices include an electroluminescence display (hereinafter, abbreviated as an ELD). Structural elements of such an ELD include an inorganic electroluminescent element (hereinafter, referred to as an inorganic EL element) and an organic electroluminescent element (hereinafter, referred to as an organic EL element). The inorganic EL elements have been employed in a flat light source. However, a high voltage of alternating current is required to drive light emitting elements.

On the other hand, in organic electroluminescent elements, a light emitting layer containing a luminous compound is sandwiched between a cathode and an anode. When electrons and positive holes are injected in the light emitting layer, the electrons and positive holes are reunited, thereby generating exciters (exciton). Successively, at the time of deactivation of the exciters, light is discharged (fluorescence·phosphorescence), whereby the organic electroluminescent elements emit light. The organic electroluminescent elements attract attention from the following viewpoints. They can emit light with a voltage of several volts to some tens of voltages. Since they are a self-emission type, they have a wide view angle and high visibility. Further, since they are complete solid elements of a thin layer type, they have advantages in space saving and portability.

Further, the organic electroluminescent elements have a prominent feature that they are a surface light source different from major light sources provided conventionally for actual use, such as light emitting diodes and cold cathode tubes. Examples of the application of this feature include a light source for illumination and a back light of various displays. In particular, the organic electroluminescent elements may be preferably employed as a backlight for liquid crystal color displays, the demand for which is markedly increased in recent years.

Incidentally, in recent years, the demand to use an organic EL luminous panel capable of saving power as an illumination light source or a display is increasing. However, the development of a large size luminous element holds difficult tasks, such as difficulty in improvement of light emission efficiency and extension of service life.

In a disclosed structure, in order to realize organic EL element with high light emission efficiency and long service life, a light emitting layer is made two or more layers, and one layer among the two or more layers is made to contain high molecule dopant (refer to Patent document 1). Similarly, in another disclosed structure, with an attempt to improve light emission efficiency and service life, all two or more layers are doped with the same or the same color fluorescent material (refer to Patent document 2). Organic EL elements are disclosed so as to specify the energy gap of a host compound contained in two or more light emitting layers and the energy gap of a raw material containing an electron transporting layer.

As a result of achievement of such research and development, currently, organic electroluminescence elements enable surface light emission with high luminance of about 100 to 100000 cd/m² with a low voltage of 10 V, and also enable full color light emission from blue to red and white color light emission by selection of kinds of fluorescent material. With regard to blue and green materials, materials with sufficiency in terms of light emission efficiency and service life characteristics have been developed. However, with regard to red material and white light emitting elements, light emission efficiency and service life are desired to be more improved. Meanwhile, many reports are made about white light emitting elements.

Methods of emitting white light include generally a method of using light emission with three wavelengths of red, green and blue, and green and a method of using light emission with two wavelengths with a complementary color relation of blue and yellow or bluish green and orange.

Further, it is generally known that the combination of three or more light emitting materials in a single layer by combination of three or more light emitting materials makes it difficult to adjust the mixing ratio of these light emitting materials because of shift of energy to long wavelength light emitting material with low energy level, and causes unevenness in performances.

Then, in a disclosed organic EL element of a lamination layer type with an object of high luminance and long service life, the organic EL element has two light emitting layers in which a light emitting layer positioned at a side near to an anode is made a yellow-red light emitting layer, a light emitting layer positioned at a side near to a cathode is made a blue light emitting layer, and three color light emitting materials are contained in the two light emitting layers, (refer to Patent document 4). Further, an organic EL element including a white light emitting layer and an assist light emitting layer with a complementary color of the white light are disclosed (refer to Patent document 5).

However, although organic EL elements according to the above-mentioned conventional techniques have been improved in terms of light emitting efficiency, luminance, and service life, they have many limitations at the time of use because of a glass substrate as a base board. Accordingly, it is not said that they are good in production suitability and handling properties, and they lack characteristics of organic EL elements which are specifically desired recently. Even if a light emitting layer is structured to be two or more layers so as to improve performances, with consideration for commercialization as product, there are limitations naturally in productivity and handling properties.

Patent document 1: Japanese Unexamined Patent Publication No. H6-33048 official report

Patent document 2: Japanese Unexamined Patent Publication No. H10-261488 official report

Patent document 3: International publication No. 2005/006816

Patent document 4: Japanese Unexamined Patent Publication No. 2001-52870 official report

Patent document 5: Japanese Unexamined Patent Publication No. 2006-210746 official report

### SUMMARY OF THE INVENTION

### Theme to be Solved by the Invention

The present invention has been achieved in view of the above-mentioned problems and situations, and a theme to be solved is to provide a white light-emitting organic electroluminescence element, wherein although the white light-emitting organic electroluminescence element is a white light-emitting organic electroluminescence element employing a flexible resin substrate, the resistance for harmful effect accompanying the flexibility is good, peel-off of the interface of a light emitting layer due to bending and loose connection are not likely to occur, and drive voltage can be made lower.

### Means for Solving the Theme

The above-mentioned theme according to the present invention is solved by the following means.
1. In a white light emitting organic electroluminescence element which includes, on a resin substrate, an anode, a cathode, at two layers of a light emitting layer A and a light emitting layer B which are provided between the anode and the cathode and contain a light emitting host and a luminescent dopant, the white light-emitting organic electroluminescence element is characterized in that the light emitting layer A contains three or more kinds of luminescent dopants including a red luminescent dopant, a green luminescent dopant, and a blue luminescent dopant, the light emitting layer B contain a luminescent dopant, the light emitting layer A and the light emitting layer B neighbor on each other, the light emitting layer A is positioned at a side near to the anode, the light emitting layer B is positioned at a side near to the cathode, and a mixing region is provided between the light emitting layer A and the light emitting layer B.
2. The white light emitting organic electroluminescence element described in the item 1 is characterized in that the thickness of the mixing region is within a range of 10 to 30% of the total thickness of the light emitting layer A and the light emitting layer B.
3. The white light emitting organic electroluminescence element described in the item 1 or the item 2 is characterized in that the layer thickness of the light emitting layer B is 1.1 to 3.0 times that of the light emitting layer A.
4. The white light emitting organic electroluminescence element described in any one of the item 1 to the item 3 is characterized in that the content of the blue luminescent dopant in the light emitting layer B is made within a range of 0.5 to 1.6 times the content of the blue luminescent dopant in the light emitting layer A.
5. The white light emitting organic electroluminescence element described in any one of the item 1 to the item 4 is characterized in that the total amount of the luminescent dopants contained in the light emitting layer A is within a range of 20 to 35 percent by weight to the total solid components of the light emitting layer A.
6. The white light emitting organic electroluminescence element described in any one of the item 1 to the item 5 is characterized in that the total amount of the luminescent dopants contained in the light emitting layer B is within a range of 7 to 20 percent by weight to the total solid components of the light emitting layer B.
7. The white light emitting organic electroluminescence element described in any one of the item 1 to the item 6 is characterized in that an order of the green luminescent dopant, the blue luminescent dopant, and the red luminescent dopant is a descending order in the content ratio of each of the red luminescent dopant, the green luminescent dopant, and the blue luminescent dopant which are contained in the light emitting layer A.
8. The white light emitting organic electroluminescence element described in any one of the item 1 to the item 7 is characterized in that the light emitting layer A and the light emitting layer B are formed by a wet process.
9. The white light emitting organic electroluminescence element described in the item 8 is characterized in that a difference in solubility parameter between respective solvents of the light emitting layer A and the light emitting layer B used in the wet process is 0.5 or less.
10. The white light emitting organic electroluminescence element described in the item 8 is characterized in that each of the respective solvents is an ester compound.
11. The white light emitting organic electroluminescence element described in any one of the item 1 to the item 10 is characterized in that the luminescent dopant is a phosphorescent compound.

### Effect of Invention

The above means of the present invention can provide a white light-emitting organic electroluminescence element, wherein although the white light-emitting organic electroluminescence element is a white light-emitting organic electroluminescence element employing a flexible resin substrate, the resistance for harmful effect accompanying the flexibility is good, peel-off of the interface of a light emitting layer due to bending and loose connection are not likely to occur, and drive voltage can be made lower.

### EMBODIMENT FOR CARRYING OUT THE INVENTION

In a white light emitting organic electroluminescence element which includes, on a resin substrate, an anode, a cathode, at two layers of a light emitting layer A and a light emitting layer B which are provided between the anode and the cathode and contain a light emitting host and a luminescent dopant, the white light-emitting organic electroluminescence element of the present invention is characterized in that the light emitting layer A contains three or more kinds of luminescent dopants including a red luminescent dopant, a green luminescent dopant, and a blue luminescent dopant, the light emitting layer B contain a luminescent dopant, the light emitting layer A and the light emitting layer B neighbor on each other, the light emitting layer A is positioned at a side near to the anode, the light emitting layer B is positioned at a side near to the cathode, and a mixing region is provided between the light emitting layer A and the light emitting layer B. This feature is a common technical feature for inventions relating to claims 1 to 11.

As the embodiment according to the invention, from the viewpoints of exhibition of the effects of the invention, the thickness of the mixing region is preferably within a range of 10 to 30% of the total thickness of the light emitting layer A and the light emitting layer B. Further, the layer thickness of the light emitting layer B is preferably 1.1 to 3.0 times that of the light emitting layer A. Furthermore, the content of the blue luminescent dopant in the light emitting layer B is preferably within a range of 0.5 to 1.6 times the content of the blue luminescent dopant in the light emitting layer A.

In the present invention, the total amount of the luminescent dopants contained in the light emitting layer A is preferably within a range of 20 to 35 percent by weight to the total solid components of the light emitting layer A. Further, the total amount of the luminescent dopants contained in the light emitting layer B is preferably within a range of 7 to 20 percent by weight to the total solid components of the light emitting layer B.

As the preferable embodiment of the present invention, an order of the green luminescent dopant, the blue luminescent dopant, and the red luminescent dopant is preferably a descending order in the content ratio of each of the red luminescent dopant, the green luminescent dopant, and the blue luminescent dopant which are contained in the light emitting layer A.

Further, in the present invention, the light emitting layer A and the light emitting layer B are formed preferably by a wet process. In this case, a difference in solubility parameter between respective solvents of the light emitting layer A and the light emitting layer B used in the wet process is preferably 0.5 or less. In addition, each of the respective solvents is preferably an ester compound.

The luminescent dopant relating to the invention is a phosphorescent compound.

Hereafter, the present invention, the structural elements of the present invention, and embodiments for carrying out the present invention will be explained in detail.

### <<Red, Green and Blue Luminescent Dopants>>

The term “red, green and blue luminescent dopant” means luminescent dopants for which any one of a fluorogenic compound and a phosphorescent compound may be used, and which have a luminescence maximum wavelength respectively in a red region (600 to 640 nm), a green range (500 to 540 nm), and a blue range (440 to 480 nm). The luminescent dopants relating to the invention will described later.

### <<Mixing Region>>

The term “mixing region” used in the present invention refers to a region where, when a light emitting layer A and a light emitting layer B are laminated, the components of both layers are mixed. When a white light emitting organic electroluminescent element of the present invention is produced, a light emitting layer B on a cathode side is laminated after lamination of a light emitting layer A on anode side. At that time, the coating liquid of the light emitting layer B becomes a state that the coating liquid forms a light emitting layer B while dissolving the coating layer of the light emitting layer A laminated previously. The light emitting layer contains its structural components in a large amount respectively. A composition in the mixing region on a side positioned near to the light emitting layer A contains the structural components of the light emitting layer A in a large amount, and a composition in the mixing region on a side positioned near to the light emitting layer B contains the structural components of the light emitting layer B in a large amount. In the present invention, the mixing region is defined from a position where the compositions of the light emitting layer B start to exist in the coating layer of the light emitting layer A to a position where the compositions of the light emitting layer A exist in the coating layer of the light emitting layer B.

In this regard, the layer thickness of the light emitting layer A is defined from a middle point of the mixing region in a direction toward the substrate to a point where the signal of a specific component element (for example, iridium, platinum, etc.) among the structural components of the light emitting layers A and B is not detected, and the layer thickness of the light emitting layer B is defined from the surface of the light emitting layer B to a middle point of the mixing region.

With the mixing region provided between the two light emitting layers, the effect to reduce a junction bather can be acquired and a drive voltage can be lowered. Further, with the formation of the mixing region, the two light emitting layers are mixed to each other so that the two light emitting layers are not peeled off from the interface. Therefore, the effects obtained from the structure that the light emitting layers are two layers, flexible resistance is good, peel-off on the interface of the light emitting layers due to bending and loose connection are not likely to occur, productivity and easiness in handling can be improved. Further, with the mixing region, the reproducibility of emission of white light at the time of current fluctuation and voltage fluctuation can be improved and color fluctuation in a CIE chromaticity diagram can be minimized.

The thickness of the mixing region is desirably 10 to 30% of the layer thickness of the total thickness of the two light emitting layers. With this ratio, the above effects exhibit more effectively.

As methods for forming the mixing region between the light emitting layers in the present invention, methods described below may be employed: a method for coating lamination layers by changing the ratio of the amount of each of the light emitting dopants respectively contained in the light emitting layer A and the light emitting layer B; a method for controlling soluble parameters (hereafter, referred to “SP value”) of solvents used for the light emitting layer A and the light emitting layer B; a method for coating lamination layers by controlling dry conditions at the time of coating of the light emitting layer A and the light emitting layer B, and a method for coating lamination layers by changing the respective concentrations of coating liquids of the light emitting layer A and the light emitting layer B.

In this connection, the term “concentration of coating liquid” means the total concentration of a light emitting host and respective light emitting dopants contained in a coating liquid. Further, the term “ratio of the amount of each of the light emitting dopants” means a ratio of the amount of each of the light emitting dopants to the total amount of the light emitting host and all the light emitting dopants.

In a method for coating lamination layers by changing the ratio of the amount of each of the light emitting dopants respectively contained in the light emitting layer A and the light emitting layer B, for example, a coating liquid A is prepared by dissolving a light emitting host and each of light emitting dopants in butyl acetate, and the resulting coating liquid A is coated on a plastic substrate so as to form a light emitting layer A. Next, after the light emitting layer A is dried naturally, a coating liquid B is prepared by changing ratio of the amount of each of the light emitting dopants in the coating liquid A, and the resulting coating liquid B is coated on the light emitting layer A. Although the resulting coating liquid B forms a light emitting layer B, the resulting coating liquid B dissolves the surface of the light emitting layer A until butyl acetate being a solvent is evaporated and mixes with the dissolved portion so that a mixing region is formed. The thickness of the mixing region can be adjusted by changing the layer thickness of each of the light emitting layer A and the light emitting layer B.

In a method for controlling the SP value of solvents used for the light emitting layer A and the light emitting layer B, for example, a coating liquid A is prepared by dissolving a light emitting host and each of light emitting dopants in butyl acetate (SP value: 8.5), and the resulting coating liquid A is coated on a plastic substrate so as to form a light emitting layer A. At this time, the light emitting layer A is dried naturally and is maintained on a condition that the solvent is not completely evaporated. Next, a coating liquid B is prepared by dissolving a light emitting host and each of light emitting dopants in isopropyl acetate (SP value: 8.4), and the resulting coating liquid B is coated on the light emitting layer A. The coating liquid B dissolves the surface of the light emitting layer A and forms a mixing region. At this time, the mixing rate becomes slightly different depending on the different value between the respective SP values of the solvents. With the utilization of this characteristic, the thickness of the mixing region between the light emitting layer A and the light emitting layer B can be adjusted.

In a method for coating lamination layers by controlling dry conditions at the time of coating of the light emitting layer A and the light emitting layer B, for example, for example, a coating liquid A is prepared by dissolving a light emitting host and each of light emitting dopants in a certain solvent, and the resulting coating liquid A is coated on a plastic substrate so as to form a light emitting layer A. Next, a drying temperature and drying wind are maintained at certain conditions, and a drying time period is controlled. Similarly to the coating liquid A, a coating liquid B is prepared by dissolving a light emitting host and a light emitting dopant in a certain solvent, and the resulting coating liquid B is coated on the light emitting layer A. Also for the coating liquid B, a drying temperature and drying wind are maintained at certain conditions, and a drying time period is controlled. The interface between the coating layer A and the coating layer B for which the drying conditions are controlled dissolves so that the coating layer A and the coating layer B mix with each other so as to form a mixing region. The thickness of the mixing region can be adjusted by changing the respective drying conditions of the coating layer A and the coating layer B.

In a method for coating lamination layers by controlling the concentration of a coating liquid of each of the coating layer A and the coating layer B, for example, a coating liquid A is prepared by dissolving a light emitting host and each of light emitting dopants in butyl acetate, and the resulting coating liquid A is coated and dried on a plastic substrate so as to form a light emitting layer A. Next, a coating liquid B is prepared by dissolving a light emitting host and each of light emitting dopants, the amount of solution of each of which is changed relative to those in the coating liquid A, into butyl acetate, the resulting coating liquid B is coated on the light emitting layer A. The coating liquid B dissolves the surface of the light emitting layer A and forms a mixing region. The thickness of the mixing region can be determined by the content of each of light emitting dopants in each of the coating layer A and the coating layer B. With the utilization of this characteristic, the thickness of the mixing region between the light emitting layer A and the light emitting layer B can be adjusted.

However, the above-mentioned methods have dependency on the characteristics of the used light emitting host and light emitting dopant, the solubility of them for used solvents, and the respective characteristics of the used solvents, the laminating methods and the laminating conditions are needed to be adjusted for each of the cases. Incidentally, the SP value will be described later.

As the measuring method of the mixing region, several methods are employable. For example, the mixing region may be measured by an X-ray photoelectron spectroscopy analysis device (XPS). With the measurement of a depth profile by this device, the thickness of a light emitting layer and the content of each of elements in the depth direction from the surface can be measured. With the measurement of the content of each of elements constituting a light emitting dopant contained in the light emitting layer, the thickness of the mixing region can be measured.

### <<Color of Emitted Light and Front Luminance of White Light Emitting Organic Electroluminescent Elements>>

Color of light emitted from the white light emitting organic electroluminescent element of the present invention and chemical compounds related to the above element is determined via spectral radiation luminance meter CS-1000 (produced by Konica Minolta Sensing, Inc.) shown in FIG. 4.16 of page 108 of “Shinhen Shikisai Kagaku Handbook (Newly Edited Color Science Handbook” (edited by Nihon Shikisai Gakkai, published by Tokyo Daigaku Shuppan Kai, 1985), and the determined results are plotted onto the CIE chromaticity diagram, whereby color is determined.

Preferred chromaticity as the white light emitting organic electroluminescent element in the present invention is in the region at an x value of 0.37±0.1 and a y value of 0.37 ±0.07.

### <Constituting Layers of Organic EL Element>

Specific examples of a preferable layer constitution of an organic EL element of the present invention are shown below; however, the present invention is not limited thereto.
(i) anode/positive hole transporting layer/electron inhibition layer/light emitting layer unit/positive hole inhibition layer/electron transporting layer/cathode
(ii) anode/positive hole transporting layer/electron inhibition layer/light emitting layer unit/positive hole inhibition layer/electron transporting layer/cathode buffer layer/cathode
(iii) anode/anode buffer layer/positive hole transporting layer/light emitting layer unit/electron transporting layer/cathode
(iv) anode/anode buffer layer/positive hole transporting layer/electron inhibition layer/light emitting layer unit/positive hole inhibition layer/electron transporting layer/cathode
(v) anode/an anode buffer layer/positive hole transporting layer/electron inhibition layer/light emitting layer unit/positive hole inhibition layer/electron transporting layer/cathode buffer layer/cathode

The white light emitting organic EL element of the present invention, the light emitting layer unit is characterized to include at least two light emitting layers.

In this regard, the above-mentioned positive hole transporting layer, the electron inhibition layer, positive hole inhibition layer, electron transporting layer, and following intermediate layer are collectively called a “carrier control layer”. The “carrier” means electron and positive hole. The “carrier transporting layer” is a layer composed of a carrier transporting material, and preferably constituted by a “p” type or “n” type semiconductor layer. Each of the ““p” type or “n” type semiconductor layer” means an organic layer which contains an electron acceptable compound or an electron releasable material and exhibits semi-conduction.

Examples of method for forming a film of each layer of the present invention include a vacuum deposition method and a wet type method. However, it is preferable to form a film by a wet type method. Film formation by the wet type process facilitates continuous film formation and coating on a resin substrate. As a film forming means of the wet type, as long as methods are the wet type, any methods may be employable. Examples of the methods include a spin coating method, a casting method, an ink-jet method, a printing method, a die coating method, and a blade coating method. For respective layers, different coating methods may be employed.

A light emitting layer unit includes at least two light emitting layers of the light emitting layer A and the light emitting layer B which contain a light emitting host and a luminescent dopant. In the light emitting layer unit, the light emitting layer A and the light emitting layer B neighbor on each other, the light emitting layer A is formed at a side near to the anode and the light emitting layer B is formed at a side near to the cathode. Further, the light emitting layer A contains three or more kinds of luminescent dopants including a red luminescent dopant, a green luminescent dopant, and a blue luminescent dopant.

In an organic EL element, the recombination of an electron and a positive hole on a certain organic molecule makes the organic molecule into an exciting state. In order to take out a lot of light, it is necessary to make a large amount of currents to flow. However, to make only one of carrier is meaningless. For one time of a recombination of carriers, one electron and one positive hole are needed. Accordingly, it is important to make electrons and positive holes to flow with the same number per a unit time and to recombine the electrons and the positive holes. With the structure that a light emitting layer includes two layers and respective luminescent dopants are made to eccentrically exist in the light emitting layer, a carrier balance between electrons and positive holes can be adjusted optimally so that improvement in external quantum efficiency and a service life can be achieved.

The light emitting layer according to the present invention is a layer in which electron and positive holes which are injected from electrodes, an electron transporting layer, and a positive hole transporting layer recombine and emit light, and a portion which emits light may be in the inside of the light emitting layer, or may be an interface between the light emitting layer and an adjacent layer. Examples of method for forming a film of two layers of the light emitting layer A and the light emitting layer B according to the present invention include a vacuum deposition method and a wet type method (a spin coating method, a casting method, an ink-jet method, a printing method, a die coating method, and a blade coating method). However, it is preferable to form a film by a wet type method. Film formation by the wet type process facilitates continuous film formation and coating on a resin substrate.

Further, at the time of film formation of the two layers of the light emitting layer A and the light emitting layer B, respective solvents used for the two layers may be the same to or different from each other. In the case where a different solvent is used depending on the kind of a light emitting layer, a difference in SP value between respective solvents of the two layers of the light emitting layer A and the light emitting layer B is preferably 0.5 or less, and more preferably 0.3 or less. As the SP value is larger, the polarity becomes lager. As respective SP values of solvents are near to each other, the solvents are more easily mixed uniformly. In the present invention, by minimizing a difference in SP value between respective solvents used for the light emitting layer A and the light emitting layer B as small as 0.5 or less, it becomes possible to form appropriately a mixing region between the light emitting layer A and the light emitting layer B. In connection, the term “SP value” is an abbreviation of Solubility Parameter, determined by quantifying solubility as an index to indicate solubility into solvent and the like, and represented with a square root of a cohesive energy density (CED). The CED represents an amount of energy needed to evaporate 1 milliliter (ml) of a solvent.

Furthermore, examples of the solvents used for film formation of the light emitting layer A and the light emitting layer B include water, and organic solvents, i.e., ketones, such as methylene chloride, methyl ethyl ketone, tetrahydrofuran, and cyclohexanone; fatty acid esters, such as ethyl acetate; halogenated hydrocarbons, such as dichlorobenzene; aromatic hydrocarbonses, such as toluene, xylene, mesitylene, and cyclohexylbenzene; aliphatic hydrocarbons, such as cyclohexane, decalin, and dodecane; alcohols, such as DMF, DMSO, n-butanol, s-butanol, and t-butanol. Among them, ester compounds are preferable. The ester compounds represent a compound produced by dehydration condensation between an organic acid, such as carboxylic acid; or an inorganic oxo acid, such as sulfuric acid; and an alcohol. Examples of organic acids include formic acid, acetic acid, citric acid, oxalic acid, and sulfonic acid, and examples of inorganic acids include hydrochloric acid, phosphoric acid, nitric acid, sulfuric acid, boric acid, and hydrofluoric acid. Examples of alcohols include methanol, ethanol, 1-propanol, 2-propanol, 1-butanol, 2-butanol, 2-methyl-1-propanol, 2-methyl-2-propanol, and 1-pentanol. Among them, in the present invention, an ester compound produced from an acetic acid and an alcohol may be preferably used. Examples of the ester compounds produced from an acetic acid and an alcohol include methyl acetate, ethyl acetate, butyl acetate, propyl acetate, isobutyl acetate, and isopropyl acetate, and these ester compounds are specifically preferably employed.

The total layer thickness of the light emitting layers according to the present invention is not limited in particular. However, from viewpoints of homogeneousness of layers, prevention of unnecessary high voltage applied at the time of light emission, and improvement of stabilization of light emission color for driving current, the total layer thickness is adjusted preferably within a range of 10 to 60 nm, more preferably within a range of 20 to 50 nm. The layer thickness of each light emitting layer is adjusted preferably within a range of 2 to 30 nm, and the layer thickness of the light emitting layer B is preferably 1.1 to 3.0 times the layer thickness of the light emitting layer A.

As long as the light emitting layer relating to the present invention satisfies the requirements specified in the present invention, the structure of the light emitting layer is not limited in particular.

Next, the light emitting hosts and luminescent dopants which are contained in the light emitting layers are explained.

### (Light Emitting Host)

The “light emitting host” contained in the light emitting layers of the white light emitting organic electroluminescent element relating to the present invention means a compound which moves energy of exciton generated by recombination of carriers on the compound to a luminescent compound (luminescent dopant: guest compound) so as to make the luminescent compound to emit light as a result of the movement, and a compound which makes a luminescent dopant to trap carriers on the compound (light emitting host), to generate exciton on the luminescent dopant, and to emit light as a result of the trapping. Accordingly, as the light emitting ability of the light emitting host itself is smaller, it is better. For example, the light emitting host may be a compound in which the phosphorescence quantum yield of phosphorescence emission at a room temperature (25° C.) is less than 0.1, and preferably less than 0.01.

With regard to the light emitting host, conventional light emitting hosts may be employed individually or in combinations of a plurality of types. In the present invention, it is preferable that at least two light emitting layers of the light emitting layer A and the light emitting layer B contain the same light emitting host. By employing a plurality of types of light emitting hosts, it is possible to regulate movement of electric charges, whereby it is possible to enhance the efficiency of organic EL elements. Further, by using two or more kinds of phosphorescent compounds used as luminescent dopants mentioned later, it becomes possible to mix different light emissions, whereby arbitrary light emission colors can be obtained.

In the present invention, it is desirable that the light emitting layer A and the light emitting layer B contain respectively the same light emitting host in an amount of at least 30% by weight or more of respective light emitting layers. In the present invention, the term “same light emitting host” refers to the case where physicochemical characteristics, such as phosphorescence emission energy and a glass transition point, are the same, or the case where the respective molecular structures of light emitting hosts are the same.

Structures of the light emitting host compounds employed in the present invention are not particularly limited. Representative examples include carbazole derivatives, triarylamine derivatives, aromatic borane derivatives, nitrogen-containing heterocyclic compounds, thiophene derivatives, furan derivatives, compounds having a basic skeleton of oligoarylene compounds, carboline derivatives, diazacarbazole derivatives (in this connection, the diazacarbazole derivative represents a compound in which at least one of the carbon atoms of the hydrocarbon ring which constitutes a carboline ring of carboline derivatives is substituted with a nitrogen atom).

The organic compound of each layer which constitutes the white light organic electroluminescence element according to the present invention, preferably contains a material having a glass transition temperature (Tg) of 100° C. or more in an amount of at least 80 weight % or more of the respective layers.

The glass transition point (Tg), as described herein, is a value which is determined based on the method specified in JIS K 7121, by use of DSC (Differential Scanning Colorimetry). The employment of the light emitting hosts having the same above physical characteristics, still more preferably, the employment of the light emitting hosts having the same molecular structure ensures homogeneous film properties over the entirety of the organic compound layer (also referred to organic layer) of an organic EL element. Further, the adjustment of the phosphorescence emission energy of the light emitting host to be 2.9 eV or more enables to suppress efficiently shifting of energy from luminescent dopants and to acquire high luminance.

The phosphorescence emission energy according to the present invention means the peak energy of a 0-0 transition band of a phosphorescence emission spectrum acquired at the time of measurement of photoluminescence of a 100 nm-thick vapor deposition film formed on a substrate (may be merely a substrate) with light emitting host. A method for measuring the 0-0 transition band of phosphorescence emission will be mentioned later.

First, a method for measuring a phosphorescence spectrum is explained. A light emitting host to be measures is dissolved in a mixed solvent of ethanol/methanol=4/1 (volume/volume) which are deoxidized well. The resulting solution is put in a cell for phosphorescence measurement, and then, irradiated with exciting light at a liquid nitrogen temperature of 77° K. At 100 ms after the irradiation of the exciting light, an emission spectrum is measured. Since a light emission life-span of phosphorescence is longer as compared with fluorescence, light remaining after 100 ms is considered to be almost phosphorescence. For a compound in which the life-span of phosphorescence is shorter than 100 ms, the emission spectrum may be measured with a shortened delay time. However, if a delay time is set so short that phosphorescence is not distinguishable from fluorescence, problems arise in that phosphorescence cannot be separated from fluorescence. Accordingly, a delay time is needed to be selected to enable the separation. Further, for a compound incapable of being dissolved in the above solvents, arbitrary solvents capable of dissolving the compound may be employed (actually, since a solvent effect in the wavelength of phosphorescence is very small, there is no problem. Next, with regard to the method for obtaining a 0-0 transition band, in the present invention, the 0-0 transition band is defined as a maximum wavelength of light emission which appears the most short wavelength side in a phosphorescence spectrum chart obtained by the above measuring method. Since the strength of a phosphorescence spectrum is usually weak in many cases, there may be a case where enlargement of the spectrum makes it difficult to classify noises and peaks. In such a case, a light emission spectrum (referred to as “regular light spectrum” for convenience sake) during irradiation of exciting light is enlarged, and the enlarged light emission spectrum is superimposed on a light emission spectrum (referred to as “phosphorescence spectrum” for convenience sake) at 100 ms after the irradiation of exciting light. Then, noises and peaks are classified by reading a peak wavelength of the phosphorescence spectrum from the regular light spectrum originated from the phosphorescence spectrum. Further, smoothing processing applied for the phosphorescence spectrum enable to classify noises and peaks so as to read peak wavelength. As the smoothing processing, a smoothing method according to Savitzky & Golay may be employed.

Moreover, the light emitting hosts used is the present invention may be a low molecule compound or a high molecular compound having a repeating unit, or may be a low molecule compound (vapor deposition polymerizable light emitting host) with a polymerizable group, such as a vinyl group and an epoxy group. Specific examples of conventionally well known light emitting host include compounds described in the following documents, JP-A Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

In the organic EL element of the present invention, since host materials achieve transportation of carriers, materials are preferred which are capable of transporting carriers. Carrier mobility is employed as a physical characteristic to represent the transportability of carriers. It is commonly noted that the carrier mobility of organic materials depends on electric field strength. Since materials which highly depend on the electric field strength tend to destroy the balance of the injection and transportation of positive holes and electrons, it is preferable to employ, as the interlayer materials and the host materials, those of which mobility exhibits minimal dependence on the electric field strength.

### (Luminescent Dopant)

As a luminescent dopant according to the present invention, although a fluorescence compound and a phosphorescent compound may be used. However, from viewpoints of acquirement of an organic EL element with higher light emission efficiency, as luminescent dopants (also simply referred to as “luminescent material”) used for light emitting layers and light emission units of the organic EL element according to the present invention, the organic EL element contains at least one or more kinds of phosphorescent compounds while containing the above-mentioned light emitting host.

### (Phosphorescent Dopant)

A phosphorescent dopant of the present invention is a compound, wherein emission from an excited triplet state thereof is observed, specifically, emitting phosphorescence at mom temperature (25° C.) and exhibiting a phosphorescence quantum yield of at least 0.01 at 25° C. The phosphorescence quantum yield is preferably at least 0.1.

The phosphorescence quantum yield can be determined via a method described in page 398 of Bunko II of Dai 4 Han Jikken Kagaku Koza 7 (Spectroscopy II of 4th Edition Lecture of Experimental Chemistry 7) (1992, published by Maruzen Co., Ltd.). The phosphorescence quantum yield in a solution can be determined using appropriate solvents. However, it is only necessary for the phosphorescent dopant of the present invention to exhibit the above phosphorescence quantum yield (at least 0.01) using any of the appropriate solvents.

Two kinds of principles regarding emission of a phosphorescent dopant are cited. One is an energy transfer-type, wherein carriers recombine on a host compound on which the carriers are transferred to produce an excited state of the host compound, and then via transfer of this energy to a phosphorescent dopant, emission from the phosphorescent dopant is realized. The other is a carrier trap-type, wherein a phosphorescent dopant serves as a carrier trap and then carriers recombine on the phosphorescent dopant to generate emission from the phosphorescent dopant. In each case, the excited state energy of the phosphorescent dopant is required to be lower than that of the host compound.

The phosphorescence emitting materials according to the present invention are complex based compounds which incorporate preferably metals in Groups 8-10 of the element periodic table, more preferably iridium compounds, osmium compounds, platinum compounds (platinum complex based compounds), and rare earth metal complexes, and of these, most preferred are iridium compounds.

Hereafter, a part of specific examples is shown.

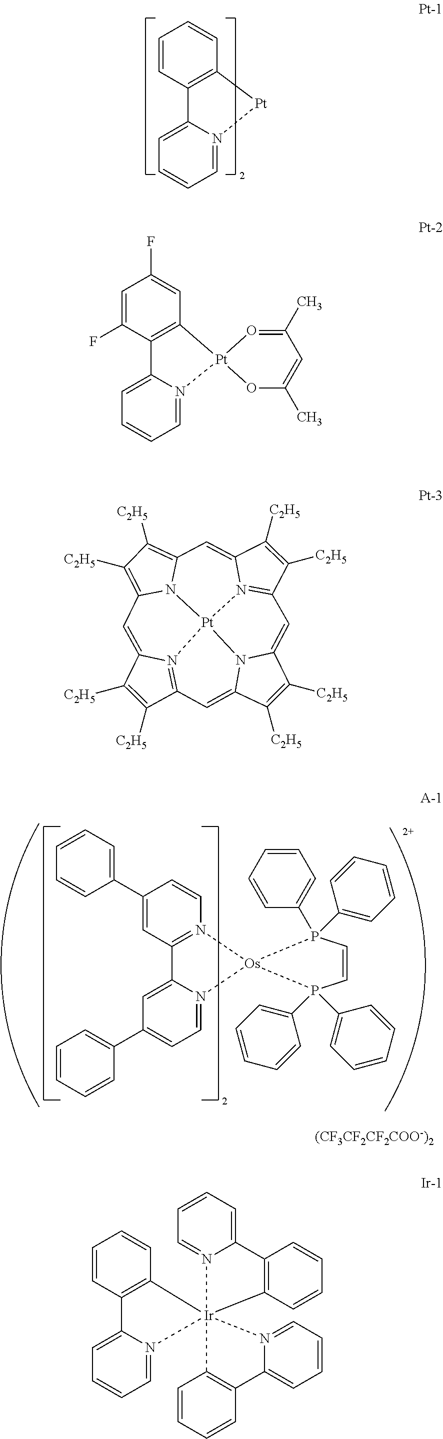

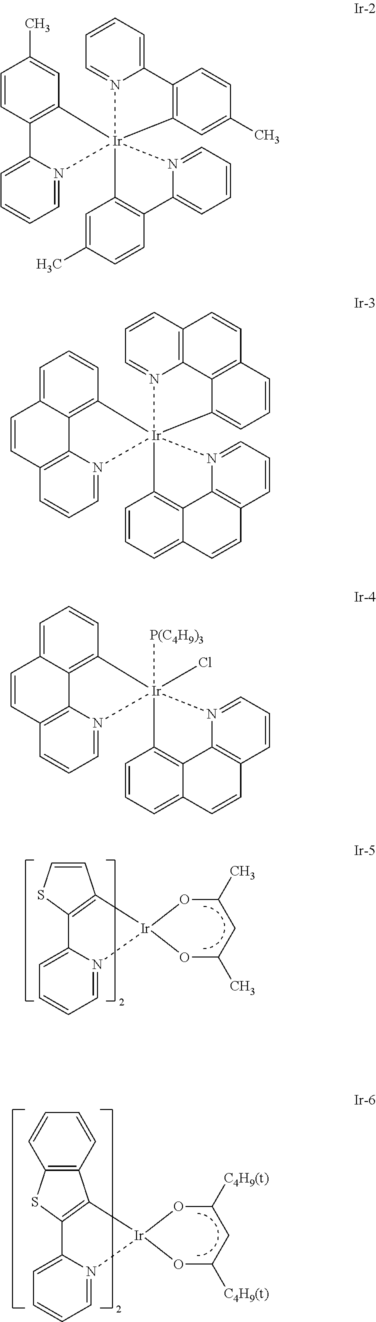

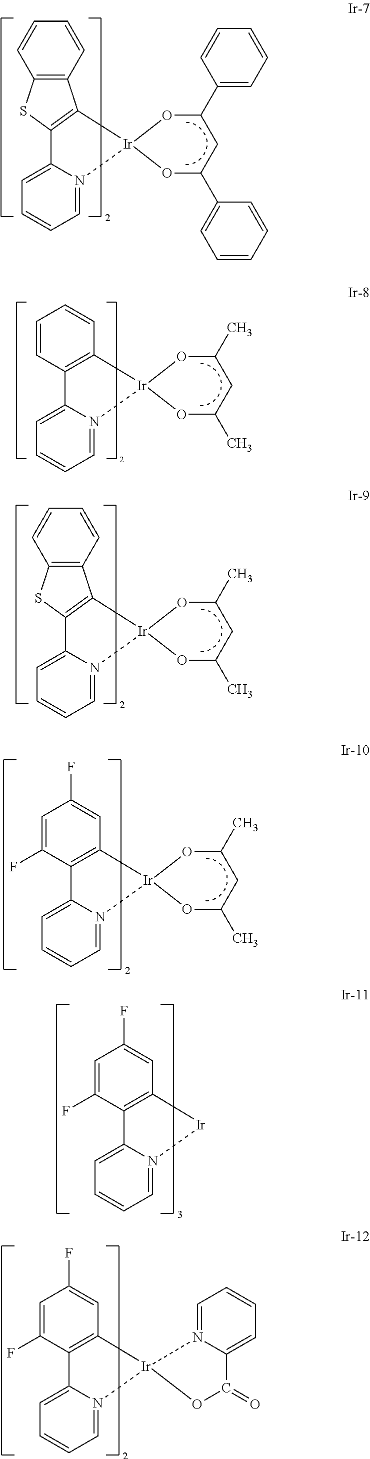

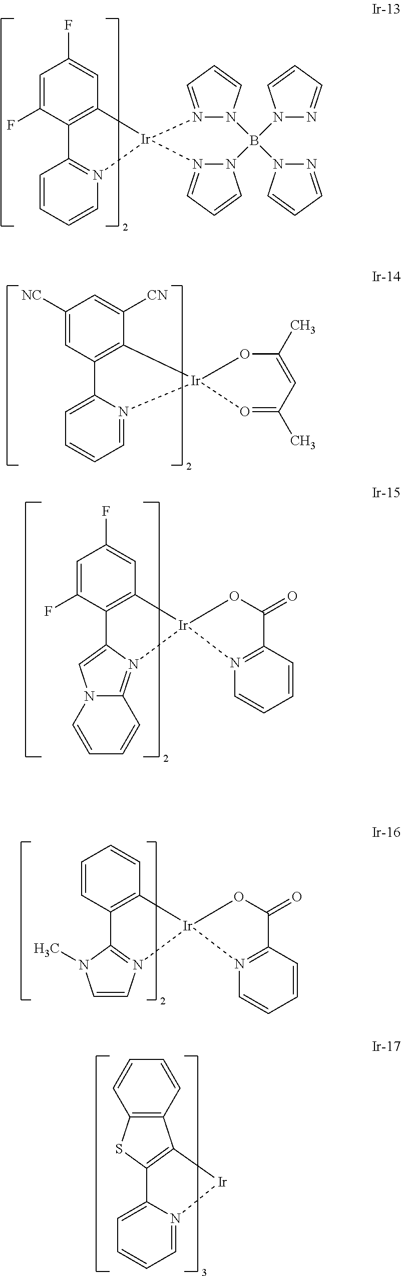

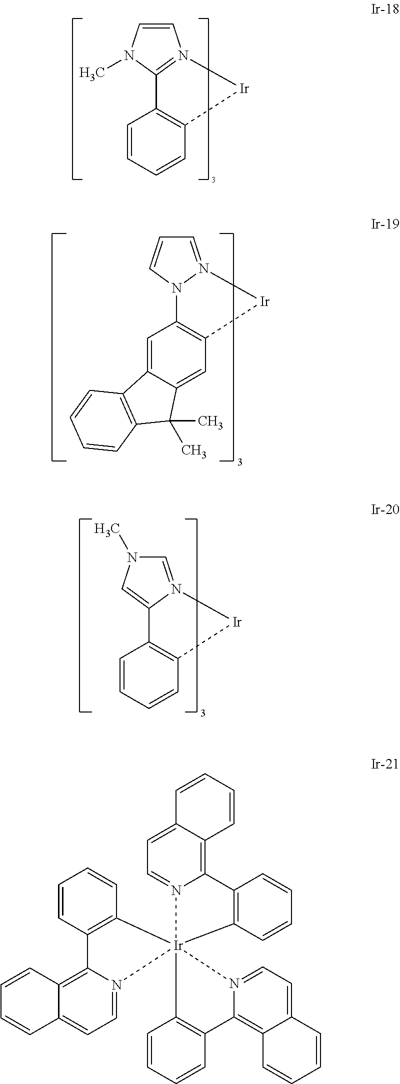

### (Fluorescent Compound)

Typical examples of the fluorescent compounds include coumari dyes, pyran dyes, cyanine dyes, croconium dyes, squarylium dyes, oxo benz anthracene dyes, fluoresceine dyes, rhodamine dyes, pyrylium dyes, perylene dyes, stilbene dyes, polythiophene dyes and rare earth complex phosphor.

Further, conventionally well-known luminescent dopants may also be used in the present invention. Examples of the known luminescent dopants include luminescent dopants disclosed in International Publication WO00/70655, Japanese Unexamined Patent Publication Nos. 2002-280178, 2001-181616, 2002-280179, 2001-181617, 2002-280180, 2001- 247859, 2002-299060, 2001-313178, 2002-302671, 2001-345183, and 2002-324679, International Publication WO02/15645, Japanese Unexamined Patent Publication Nos. 2002-332291, 2002-50484, 2002-332292, 2002-83684, 2002-540572, 2002-117978, 2002-338588, 2002- 170684, and 2002-352960, International Publication WO01/93642, Japanese Unexamined Patent Publication Nos. 2002-50483, 2002-100476, 2002-173674, 2002-359082, 2002-175884, 2002-363552, 2002-184582, 2003-7469, 2002-525808, 2003-7471, 2002-525833, 2003-31366, 2002-226495, 2002-234894, 2002-235076, 2002-241751, 2001-319779, 2001-319780, 2002-62824, 2002-100474, 2002-203679, 2002-343572, and 2002-203678.

### <<Content of Luminescent Dopant>>

In the present invention, the light emitting layer A contains three or more kinds of luminescent dopants including a red luminescent dopant, a green luminescent dopant, and a blue luminescent dopant, and the light emitting layer B contains a blue luminescent dopant. With this structure, energy transition to the short wave luminescent dopant contained in the light emitting layer B increases, and light emission efficiency improves.

In the present invention, it is preferable that the content of the blue luminescent dopant in the light emitting layer B is made within a range of 0.5 to 1.6 times the content of the blue luminescent dopant in the light emitting layer A. It is more preferable that the total amount of the luminescent dopants contained in the light emitting layer A is preferably within a range of 20 to 35 percent by weight to the total solid components in the light emitting layer A. In the present invention, in the specifically preferable embodiment, an order of the green luminescent dopant, the blue luminescent dopant, and the red luminescent dopant is a descending order in the content ratio of each of the red luminescent dopant, the green luminescent dopant, and the blue luminescent dopant which are contained in the light emitting layer A. As a ratio of each of the luminescent dopants, it is preferable that a ratio of the green luminescent dopant is 11.0 to 17.0 weight %, a ratio of the blue luminescent dopant is 7.0 to 13.0 weight %, and a ratio of the red luminescent dopant is 0.5 to 5.0 weight %. The luminescent dopants contained in the light emitting layer A are not limited to the above, and conventional well-know dopants may be employed.

The reason why a descending order in the content ratio of these luminescent dopants in the solid components in the light emitting layer A is made an order of the green luminescent dopant, the blue luminescent dopant, and the red luminescent dopant is derived from easiness in shifting of energy in respective luminescent dopants. Energy (carrier) easily moves to the direction of a red luminescent dopant than to a green and blue luminescent dopants. This means that red light is emitted most easily. For this reasons, in order to emit green light and blue light, the ratio of each of the green luminescent dopant and the blue luminescent dopant is needed to be increased. Further, in order to acquire white light, the adjustment of chromaticity is needed for green, blue, and red. On the other hand, if the concentration of a luminescent dopant is too high, the efficiency of phosphorescence emission is lowered due to the phenomenon of T-T dissipation. In contrast, if the concentration of a luminescent dopant is too low, a carrier transporting ability is worsened and light emission efficiency is lowered. In order to obtain a white and efficient organic EL element, it is desirable to contain the luminescent dopants in the above-mentioned respective contents.

Moreover, it is desirable that the total amount of the luminescent dopants contained in the light emitting layer B is made within a range of 7 to 20 percent by weight to the total solid components of the light emitting layer B.

With the adjustment that a descending order in the content ratio of these luminescent dopants in the solid components in the light emitting layer A is made an order of the green luminescent dopant, the blue luminescent dopant, and the red luminescent dopant, and that the content of the blue luminescent dopant contained in the light emitting layer A and the light emitting layer B is made within the above-mentioned range, white light with high light emission efficiency can be acquired. The reason why such light emission efficiency becomes high relates to the position of the recombination of electrons and positive holes. In the case where the light emitting layer is a single layer, the position of the recombination of electrons and positive holes locates an interface portion relative to a neighboring layer at a side near to an anode in the light emitting layer. On this position, light emission with high efficiency may not be obtained in many cases. Therefore, the light emitting layer is made a tow layer structure, and the blue luminescent dopant made to be contained in a light emitting layer located at a side near to the cathode changes carrier balance, thereby moving the position of the recombination of electrons and positive holes to a central portion of the light emitting layer. The movement of the position of the recombination to the central portion makes electrons and positive holes to move smoothly and facilitates the recombination of them. As a result, a white light emitting organic electroluminescent element with high light emission efficiency can be produced.

### <Positive Hole Transporting Layer>

A positive hole transporting layer contains a positive hole transporting material having a function of transporting positive holes, and in a broad meaning, a positive hole injection layer and an electron inhibition layer are also included in the positive hole transporting layer. The positive hole transporting layer may be provided with the structure of a single layer or a plurality of layers.

In the present invention, it is desirable that a positive hole transporting layer is a so-called p type semiconductor layer. The interpreted reason is that effects are recognized in a driving voltage made to be lower, the concentration of positive holes is increased by doping of carrier (electron) acceptor, and the mobility of positive holes via hopping conduction is made high by forming a high HOMO level.

A positive hole transporting material is those having any one of a property to inject or transport a positive hole or a barrier property to an electron, and may be either an organic substance or an inorganic substance. Examples of the positive hole transporting materials include a triazole derivative, an oxadiazole derivative, an imidazole derivative, a polyarylalkane derivative, a pyrazolone derivative, a phenylenediamine derivative, an arylamine derivative, an amino substituted chalcone derivative, an oxazole derivatives, a styrylanthracene derivative, a fluorenone derivative, a hydrazone derivative, a stilbene derivative, a silazane derivative, an aniline type copolymer, or conductive polymer oligomer and specifically preferably such as thiophene oligomer. As a positive hole transporting material, those described above can be utilized, however, it is preferable to utilized a porphyrin compound, an aromatic tertiary amine compound and a styrylamine compound, and specifically preferably an aromatic tertiary amine compound. Typical examples of an aromatic tertiary amine compound and a styrylamine compound include N,N,N′,N′-tetraphenyl-4,4′-diaminophenyl; N,N′-diphenyl-N,N′-bis(3-methylphenyl)-(1,1′-biphenyl)-4,4′-diamine (TDP); 2,2-bis(4-di-p-tolylaminophenyl)propane; 1,1-bis(4-di-p-tolylaminophenyl)cyclohexane; N,N,N′,N′ -tetra-p-tolyl 4,4′-diaminobiphenyl; 1,1-bis(4-di-p-tolylaminophenyl)-4-phenylcyclohexane; bis(4-dimethylamino-2-metyl)phenylinethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminophenylether; 4,4′-bis(diphenylamino)quadriphenyl; N,N,N-tri(p-tolyl)amine; 4-(di-p-tolylamino)-4′-[4-(di-p-triamino)styryl]stilbene; 4-N,N-diphenylamino-(2-diphenylvinyl)benzene; 3-methoxy-4′-N,N-diphenylaminostilbene; and N-phenylcarbazole, in addition to those having two condensed aromatic rings in a molecule described in U.S. Pat. No. 5,061,569, such as 4,4′-bis[N-(1-naphthyl)-N-phenylammo]biphenyl (NDP), and 4,4′,4″-tris[N-(3-methylphenyl)-N-phenylamino]triphenylamine (MDTDATA), in which three of triphenylamine units are bonded in a star burst form, described in JP-A No. 4-308688. Polymer materials, in which these materials are introduced in a polymer chain or constitute the main chain of polymer, can be also utilized. Further, an inorganic compound such as a p type-Si and a p type-SiC can be utilized as a positive hole injection material and a positive hole transporting material

Examples of materials of the carrier (electron) acceptor include well-know materials, fore examples, materials disclosed in Japanese Unexamined Patent Publication No. H11-251067, J. Huang et al. reference (Applied Physics Letters 80(2002), p. 139), Japanese Unexamined Patent Publication Nos. 4-297076, 2000-196140, 2001-102175, and 2004-281371, and J. Appl. Phys., 95, 5773 (2004). Further, materials shown in general formulas (1) to (7) in Japanese Patent Application No. 2004-215727 may be also employed.

The above positive hole transporting materials and carrier (electron) acceptors can be formed in a thin film by use of a vacuum deposition method and a wet type method (a spin coating method, a casting method, an ink-jet method, a printing method, a die coating method, and a blade coating method). However, it is preferable to form a film by a wet type method. Film formation by the wet type process facilitates continuous film formation and coating on a resin substrate.

In the present invention, an acceptor-containing average volume concentration, which cannot be specified depending on the kind of a material, may 0.1% to 30%, and it is preferable that at least a region having a different concentration of 3% or more from the average concentration exists. Further, a difference between the highest concentration and the lowest concentration is 1 to 30%, preferably 1 to 20%, and more preferably 1 to 10%. The layer thickness ratio of the highest concentration region is 1 to 50%, and more preferably 2 to 45%.

A layer thickness is usually about 1nm -1 μm, and preferably 5 to 200 nm. In a region within 5 nm from an organic interface neighboring a positive hole transporting layer and a cathode side, as the concentration of carrier (electron) acceptor is as lower as possible in a range that conductivity is not spoiled, it is preferable from the viewpoints of continuous driving life-span.

### <Electron Transporting Layer>

An electron transporting layer is comprised of a material having a function to transfer an electron, and an electron injection layer and a positive hole inhibition layer are included in an electron transporting layer in a broad meaning. A single layer or plural layers of an electron transporting layer may be provided.

In the present invention, it is desirable that an electron transporting layer is a so-called n type semiconductor layer. The interpreted reason is that effects are recognized in a driving voltage made, the concentration of electrons is increased by doping of carrier (electron) acceptor, and the mobility of electrons via hopping conduction is made high by forming a high HOMO level.

As long as materials has a function of transporting electrons injected from cathode to the light emitting layers, known materials may be employed as electron transporting materials. Examples of these compounds include a nitro-substituted fluorene derivative, a diphenylquinone derivative, a thiopyradineoxide derivative, carbodiimide, a fluorenylidenemethane derivative, anthraquinonedimethane, an anthraquinone derivative, an anthrone derivative and an oxadiazole derivative. Further, a thiazole derivative in which an oxygen atom in the oxadiazole ring of the above-described oxadiazole derivative is substituted by a sulfur atom, and a quinoxaline derivative having a quinoxaline ring which is known as an electron attracting group can be utilized as an electron transporting material. Polymer materials, in which these materials are introduced in a polymer chain or these materials form the main chain of polymer, can be also utilized. Further, a metal complex of a 8-quinolinol derivative such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, can be also utilized as an electron transporting material. Further, metal-free or metal phthalocyanine, or those the terminal of which is substituted by an alkyl group and a sulfonic acid group, can be preferably utilized as an electron transporting material.

As the carrier donor material according to the present invention, well-known material can be employed. Examples of the carrier donor materials include materials disclosed in Japanese Unexamined Patent Publication Nos. 4-297076, 10-270172, 2000-196140, 2001-102175, and J. Appl. Phys., 95, 5773 (2004). Further, materials shown in general formulas (8) to (10) in Japanese Patent Application No. 2004-215727 may be also employed. In the present invention, such an electron transporting layer having a high n type is used together with the p type semiconductor layer according to the present invention, whereby it becomes possible to produce elements with a low power consumption.

The above electron transporting materials and carrier (electron) donors can be formed in a thin film by use of a vacuum deposition method and a wet type method (a spin coating method, a casting method, an ink-jet method, a printing method, a die coating method, and a blade coating method). However, it is preferable to form a film by a wet type method. Film formation by the wet type process facilitates continuous film formation and coating on a resin substrate.

A preferable donor vapor deposition condition cannot be specified depending on the kind of a material. However, in the present invention, a donor-containing average volume concentration may 5 to 95%, and it is preferable that at least a region having a different concentration of 5% or more in a difference between the highest concentration and the lowest concentration exists. Further, a difference between the highest concentration and the lowest concentration is 20 to 90%. The highest concentration is preferably 15 to 95%, and more preferably 25 to 90%. The layer thickness ratio of the highest concentration region in the electron transporting layer is 1 to 50%, and more preferably 2 to 45%. A layer thickness is usually about 1 nm-1 μm, and preferably 5 to 200 nm. In a region at a ⅓ thickness of the electron transporting layer according to the invention from an organic interface neighboring a positive hole transporting layer, as the concentration of carrier donor is as lower as possible in a range that conductivity is not spoiled, it is preferable from the viewpoints of continuous driving life-span. A donor volume concentration which may be different depending on the kind of a material is 5 or less in many cases. In the present invention, if three or more regions where the donor volume concentration is different by 5% or more exist, there may a case where light emission efficiency is improved more. On example of the case is a case where the donor volume concentration changes continuously. Examples of the term “regional” in the present invention include a case where layer structures where the donor volume concentration is different by 1 nm or more are combined arbitrarily. Even in this case, a difference between the highest concentration and the lowest concentration in the donor volume concentration is 5% or more.

### <Injection Layer: Electron Injection Layer, Positive Hole Injection Layer>

An injection layer is a layer which is arranged between an electrode and an organic layer to decrease an operating voltage and to improve an emission luminance, which is detailed in volume 2, chapter 2 (pp. 123-166) of “Organic EL Elements and Industrialization Front thereof (Nov. 30th 1998, published by N. T. S. Corp.)”, and includes a positive hole injection layer (an anode buffer layer) and an electron injection layer (a cathode buffer layer).

An injection layer is appropriately provided and includes an electron injection layer and a positive hole injection layer, which may be arranged between an anode and an emitting layer or a positive transfer layer, and between a cathode and an emitting layer or an electron transporting layer.

An anode buffer layer (a positive hole injection layer) is also detailed in such as JP-A Nos. 9-45479, 9-260062 and 8-288069, and specific examples include such as a phthalocyanine buffer layer comprising such as copper phthalocyanine, an oxide buffer layer comprising such as vanadium oxide, an amorphous carbon buffer layer, and a polymer buffer layer employing conductive polymer such as polythiophene. The materials which are disclosed in JP-A No. 2003-519432 are preferably used.

A cathode buffer layer (an electron injection layer) is also detailed in such as JP-A Nos. 6-325871, 9-17574 and 10-74586, and specific examples include a metal buffer layer comprising such as strontium and aluminum, an alkali metal compound buffer layer comprising such as lithium fluoride, an alkali earth metal compound buffer layer comprising such as magnesium fluoride, and an oxide buffer layer comprising such as aluminum oxide.

The above-described buffer layer (injection layer) is preferably a very thin layer, and the layer thickness is preferably in a range of 0.1 nm-5 μm although it depends on a raw material.

Examples of method for forming the buffer layer (injecting layer) include a vacuum deposition method and a wet type method (a spin coating method, a casting method, an ink-jet method, a printing method, a die coating method, and a blade coating method). However, it is preferable to form a film by a wet type method. Film formation by the wet type process facilitates continuous film formation and coating on a resin substrate.

### <Inhibition Layer: Positive Hole Inhibition Layer, Electron Inhibition Layer>

A positive hole inhibition layer has a function of a positive hole transporting layer in a broad meaning, is composed of a positive hole inhibition material which has a function capable of transporting electrons and a remarkably small ability to transport positive holes, and can increase the probability of the recombination of electrons and positive holes by blocking positive holes while transporting electrons. The positive hole inhibition layer of the white light emitting organic EL element is preferably disposed so as to neighbor the light emitting layers.

An inhibition layer is appropriately provided in addition to the basic constitution layers composed of organic thin layers as described above. Examples are described in such as JP-A Nos. 11-204258 and 11-204359 and p. 237 of “Organic EL Elements and Industrialization Front Thereof (Nov. 30 (1998), published by N. T. S Corp.)” is applicable to a positive hole inhibition (hole block) layer according to the present invention.

In the present invention, it is desirable that more than 50 weight % or more of the compound contained in the positive hole inhibition layer has an ionization potential of 0.2 eV or more larger relative to the light emitting host compound in the above-mentioned shortest wave light emitting layer.

If the positive hole inhibition layer according to the present invention includes the electron donor, since electron density increases, it is preferable for lowering of a voltage.

The ionization potential is defined with energy necessary for discharging electrons positioned at a HOMO (highest occupied molecular orbital) level in a compound to a vacuum level, and, for example, may be obtained by the following methods.
(1) A value (eV unit conversion value) is calculated by structural optimization by use of Gaussian 98 (Gaussian98, Revision A.11.4, M. J. Frisch, et al, Gaussian, Inc., Pittsburgh Pa. 2002), which is software for molecular orbital calculation and manufactured by U.S. Gaussian Corporation, with a key word of B3LYP/6-31G*, and the calculated value is rounded off at the second place of the decimal point, whereby the ionization potential can be obtained. The background that this calculated value is effective is because correlation between a calculated value obtained by this technique and an experimental value is high.
(2) The ionization potential may be obtained a directly- measuring method with photoelectron spectroscopy. For example, a low energy electron spectrum apparatus “Model AC-1” manufactured by Riken Keiki Co., Ltd., and a method known as ultraviolet photoelectron spectroscopy may be employed.

On the other hand, an electron inhibition layer has a function of a positive hole transporting layer in a broad meaning, is composed of a material which has a function capable of transporting positive holes and a remarkably small ability to transport electros, and can increase the probability of the recombination of electrons and positive holes by blocking electrons while transporting positive holes. The electron inhibition layer used preferably in the present invention is a material of the positive hole transporting layer. Further, it the electron acceptor is contained, the effect of lowering of a voltage can be obtained.

The layer thickness of each of the positive hole inhibition layer and the electron inhibition layer according to the present invention is preferably 3 to 100 nm, and more preferably 5 to 30 nm.

Examples of method for forming the above inhibition layer include a vacuum deposition method and a wet type method (a spin coating method, a casting method, an ink-jet method, a printing method, a die coating method, and a blade coating method). However, it is preferable to form a film by a wet type method. Film formation by the wet type process facilitates continuous film formation and coating on a resin substrate.

### <Anode>

As an anode according to an organic EL element of the present invention, those comprising metal, alloy, a conductive compound, which is provided with a large work function (not less than 4 eV), and a mixture thereof as an electrode substance are preferably utilized. Specific examples of such an electrode substance include a conductive transparent material such as metal like Au, CuI, indium tin oxide (ITO), SnO₂ and ZnO. Further, a material such as IDIXO (In₂O₃—ZnO), which can prepare an amorphous and transparent electrode, may be also utilized. As for an anode, these electrode substances may be made into a thin layer by a method such as evaporation or spattering and a pattern of a desired form may be formed by means of photolithography, or in the case of requirement of pattern precision is not so severe (not less than 100 μm), a pattern may be formed through a mask of a desired form at the time of evaporation or spattering of the above-described substance. Alternatively, when coatable materials such as organic electrically conductive compounds are employed, it is possible to employ a wet system filming method such as a printing system or a coating system. When emission is taken out of this anode, the transmittance is preferably set to not less than 10% and the sheet resistance as an anode is preferably not more than a few hundreds Ω/□. Further, although the layer thickness depends on a material, it is generally selected in a range of 10 nm-1,000 nm and preferably of 10 nm-200 nm.

### <Cathode>

On the other hand, as a cathode according to the present invention, metal, alloy, a conductive compound and a mixture thereof, which have a small work function (not more than 4 eV), are utilized as an electrode substance. Specific examples of such an electrode substance includes such as sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture and rare earth metal. Among them, with respect to an electron injection property and durability against such as oxidation, preferable are a mixture of electron injecting metal with the second metal which is stable metal having a work function larger than electron injecting metal, such as a magnesium/silver mixture, a magnesium/aluminum mixture, a magnesium/indium mixture, an aluminum/aluminum oxide (Al₂O₃) mixture and a lithium/aluminum mixture, and aluminum. As for a cathode, these electrode substances may be made into a thin layer by a method such as evaporation or spattering. Further, the sheet resistance as a cathode is preferably not more than a few hundreds Ω/□ and the layer thickness is generally selected in a range of 10 nm-5 μm and preferably of 50 nm-200 nm. Herein, to transmit emission, either one of an anode or a cathode of an organic EL element is preferably transparent or translucent to improve the mission luminance.

Further, after forming, on the cathode, the above metals at a film thickness of 1 nm-20 nm, it is possible to prepare a transparent or translucent cathode in such a manner that electrically conductive transparent materials are prepared thereon. By applying the above, it is possible to produce an element in which both anode and cathode are transparent.

The white light emitting organic EL element according to the present invention is characterized in that a resin substrate is employed as the substrate.

In the resin substrate used in the present invention, the kind of resin is not limited in particular. The resin substrate has preferably flexibility and is transparent.

Resin film includes such as: polyesters such as polyethylene terephthalate (PET) and polyethylene naphthalate (PEN); polyethylene, polypropyrene; cellulose esters or their derivatives such as cellophane, cellulose diacetate, cellulose triacetate, cellulose acetate butylate, cellulose acetate propionate (CAP), cellulose acetate phthalate (TAC) and cellulose nitrate; polyvinylidene chloride, polyvinyl alcohol, polyethylene vinyl alcohol, syndiotactic polystyrene, polycarbonate, norbomene resin, polymethylpentene, polyether ketone, polyimide, polyether sulfone (PES), polyphenylene sulfide, polysulfones, polyetherimide, polyether ketone imide, polyimide, fluororesin, Nylon, polymethylmethacrylate, acrylic resin, polyacrylate; and cycloolefine resins such as ARTON (produced by JSR Co. Ltd.) and APEL (produce by Mitsui Chemicals, Inc.)

As the resin substrate which has flexibility, i.e., a flexible resin substrate, it is desirable that a tensile strength is 20 to 80 kg/mm², an elastic modulus in an arbitrary direction parallel to a substrate surface is 1000 to 2500 kg/mm², and the degree of ultimate elongation in an arbitrary direction parallel to a substrate surface is 5% or more.

On the surface of a resin film, formed may be a film incorporating inorganic and organic compounds or a hybrid film of both. Bather films are preferred at a water vapor permeability (25±0.5° C., and relative humidity (90±2)% RH) of at most 0.01 g(m²·24 h), determined based on JIS K 7129-1992. Further, high barrier films are preferred at an oxygen permeability of at most 1×10⁻³ ml/(m²·24 h·MPa), and at a water vapor permeability of at most 10⁻⁵ g/(m²·24 h), determined based on JIS K 7126-1992.

As materials forming a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

### <<Method for Forming a Barrier Film>>

Barrier film forming methods are not particularly limited, and examples of employable methods include a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143. Examples of opaque support substrates include metal plates such aluminum or stainless steel, films, opaque resin substrates, and ceramic substrates.

The external takeoff efficiency of light emission of the white light emitting organic EL element according to the present invention in a room temperature is preferably 1% or more, and more preferably 5% or more.

Herein, external takeoff quantum efficiency (%)=(the number of photons emitted to the outside of an organic EL element)/(the number of electrons made to flow to the organic EL element)×100

Further, hue improving filters, such as color filters may be employed as combination use, and also, color conversion filter to convert light emission color from an organic EL element into multiple colors by use of a phosphor.

### <<Sealing>>

As sealing means employed in the present invention, listed maybe, for example, a method in which sealing members, electrodes, and a supporting substrate are subjected to adhesion via adhesives. A sealing member is preferably seal so as to cover the entirety of a plurality of light emitting layers located on a surface opposite to a light emitting surface of a surface light emitting panel in which a plurality of organic EL elements are arranged side by side.

Specifically, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type ultraviolet radiation curable type epoxy resin adhesives. In addition, since an organic EL element is occasionally deteriorated via a thermal process, those are preferred which enable adhesion and curing between room temperature and 80° C.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials forming the aforesaid film may be those which exhibit functions to retard penetration of those such as moisture or oxygen which results in deterioration. For example, it is possible to employ silicon oxide, silicon dioxide, and silicon nitride. Still further, in order to improve brittleness of the aforesaid film, it is preferable that a laminated layer structure is formed, which is composed of these inorganic layers and layers composed of organic materials.

Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method. In a gas phase and a liquid phase, it is preferable to inject inert gases such as nitrogen or argon, and inactive liquids such as fluorinated hydrocarbon or silicone oil into the space between the sealing member and the surface region of the organic EL element.

Further, it is possible to form vacuum. Still further, it is possible to enclose hygroscopic compounds in the interior. Examples of hygroscopic compounds include metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides.

### <<Protective Film and Protective Plate>>

The aforesaid sealing film on the side which nips the organic layer and faces the support substrate or on the outside of the aforesaid sealing film, a protective or a protective plate may be arranged to enhance the mechanical strength of the element. Specifically, when sealing is achieved via the aforesaid sealing film, the resulting mechanical strength is not always high enough, whereby it is preferable to arrange the protective film or the protective plate described above. Usable materials for these include glass plates, polymer plate-films, and metal plate-films which are similar to those employed for the aforesaid sealing. However, in terms of light weight and a decrease in thickness, it is preferable to employ polymer films.

### <<Preparation Method of Organic EL Element>>

As one example of the preparation method of the organic EL element of the present invention, the preparation method of the organic EL element composed of anode/positive hole injection layer/positive hole transporting layer/light emitting layer/electron transporting layer/electron injection layer/cathode will be described.

Initially, a thin film composed of desired electrode substances, for example, anode substances is formed on an appropriate base material to reach a thickness of at most 1 μm but preferably 10 nm-200 nm, employing a method such as vapor deposition or sputtering, whereby an anode is prepared. Subsequently, on the above, formed are organic compound thin layers including a positive hole injection layer, a positive hole transporting layer, a light emitting layer, a positive hole inhibition layer, an electron transporting layer, and an electron injection layer, which are organic EL element materials.

Methods to form each of these layers include, as described above, a vapor deposition method and a wet process (such as a spin coating method, a cast method, an ink-jet method and a printing method). In view of easy formation of a homogeneous film and rare formation of pin holes, preferred coating methods are a vapor deposition method, a spin coating method, an ink-jet method and a printing method. Different coating methods may be applied for different layers. When a vapor deposition method is adopted for making a layer, the condition of a vapor deposition varies depending on the compounds employed. It is generally preferable to select the conditions of: heating temperature of a boat, 50° C. to 450° C.; vacuum degree, 10⁻⁶ Pa to 10⁻² Pa; deposition rate, 0.01 nm/sec to 50 nm/sec; temperature of a substrate, −50° C. to 300° C.; and layer thickness, 0.1 nm to 5 μm, more preferably to select the thickness of from 5 nm to 200 nm. After forming these layers, a thin layer composed of cathode materials is formed on the above layers via a method such as vapor deposition or sputtering so that the film thickness reaches at most 1 μm, but is preferably in the range of 50 nm-200 nm, whereby a cathode is arranged, and the desired organic EL element is prepared. When an organic EL element of the present invention is prepared, it is preferred to make all of the layers from a cathode layer to a positive hole injection layers without interruption and with one time evacuation. However, it may be possible to take out the intermediate product and may apply it a different layer making process. For that purpose, it is required to carry out the operation under a dry inert gas atmosphere.

In the present invention, at the time of coating of organic layer a wet method for film formation, it is desirable to conduct the coating under an inert atmosphere. Although inert gas means nitrogen, carbon dioxide, helium, neon, argon, krypton, xenon, and radon, nitrogen is desirable as and inert gas from the viewpoints of availability at low cost. Further, under the inert atmosphere, each of the concentration of oxygen and the concentration of moisture is preferably in a range of 1 to 1000 ppm, and more preferably in a range of 1 to 100 ppm.

Examples of liquid medium which dissolves or disperses organic EL material according to the present invention include water, and organic solvents, i.e., ketones, such as methylene chloride, methyl ethyl ketone, tetrahydrofuran, and cyclohexanone; fatty acid esters, such as ethyl acetate; halogenated hydrocarbons, such as dichlorobenzene; aromatic hydrocarbonses, such as toluene, xylene, mesitylene, and cyclohexylbenzene; aliphatic hydrocarbons, such as cyclohexane, decalin, and dodecane; alcohols, such as DMF, DMSO, n-butanol, s-butanol, and t-butanol. Among them, ester compounds are preferable. In the present invention, the liquid media used for coating one layer may be a single kind, or may be used in combination of two or more kinds of solvents.

As a dispersing method, the materials can be dispersed by dispersing methods, such as a supersonic wave, high shearing dispersion, and media dispersion.

In the present invention, in the case where a single layer includes two or more kinds of compounds such as light emitting host, luminescent dopant, and so on, the two or more kinds of compounds may be dissolved in the same solvent and coated. Alternatively, the two or more kinds of compounds may be dissolved separately in respective solvents and the respective resulting solutions are mixed on a substrate.

After formation of a positive hole injecting layer to electron transporting layer, an electron injecting layer composed of inorganic metal such as lithium fluoride. In this case, the electron injecting layer may formed by vapor deposition method.

On the electron injecting layer, a thin layer composed of material for cathode with a thickness of 1 μm or less, or preferably 50 to 200 nm is formed by methods such as vapor deposition and sputtering so as to fowl a cathode, whereby a desired organic EL element can be obtained

Further, by reversing the preparation order, it is possible to achieve preparation in order of a cathode, an electron injection layer, an electron transporting layer, a light emitting layer, a positive hole transporting layer, a positive hole injection layer, and an anode. When direct current voltage is applied to the multicolor display device prepared as above, the anode is employed as +polarity, while the cathode is employed as—polarity. When 2 V-40 V is applied, it is possible to observe light emission. Further, alternating current voltage may be applied. The wave form of applied alternating current voltage is not specified.

It is generally known that an organic EL element emits light in the interior of the layer exhibiting the refractive index (being about 1.6—about 2.1) which is greater than that of air, whereby only about 15%—about 20% of light generated in the light emitting layer is extracted. This is due to the fact that light incident to an interface (being an interface of a transparent substrate to air) at an angle of θ which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction of the element side surface.

Means to enhance the efficiency of the aforesaid light extraction include, for example, a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods while combined with the organic EL element of the present invention. Of these, it is possible to appropriately employ the method in which a flat layer of a refractive index which is equal to or less than the substrate is introduced between the substrate and the light emitting body and the method in which a diffraction grating is formed between the substrate and any of the layers such as the transparent electrode layer or the light emitting layer (including between the substrate and the outside).

By combining these means, the present invention enables the production of elements which exhibit higher luminance or excel in durability.

When a low refractive index medium of a thickness, which is greater than the wavelength of light, is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5—about 1.7, the refractive index of the low refractive index layer is preferably at most approximately 1.5, but is more preferably at most 1.35.

Further, thickness of the low refractive index medium is preferably at least two times the wavelength in the medium. The reason is that when the thickness of the low refractive index medium reaches nearly the wavelength of light so that electromagnetic waves oozed via evernescent enter into the substrate, effects of the low refractive index layer are lowered.

The method in which the interface which results in total reflection or a diffraction grating is introduced in any of the media is characterized in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light emitting layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced.

As noted above, a position to introduce a diffraction grating may be between any layers or in a medium (in a transparent substrate or a transparent electrode). However, a position near the organic light emitting layer, where light is generated, is desirous. In this case, the cycle of the diffraction grating is preferably about ½—about 3 times the wavelength of light in the medium. The preferable arrangement of the diffraction grating is such that the arrangement is two-dimensionally repeated in the form of a square lattice, a triangular lattice, or a honeycomb lattice.

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 μm-100 μm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed maybe, for example, A shaped stripes of an apex angle of 90 degrees and a pitch of 50 μm formed on a base material, a shape in which the apex angle is rounded, a shape in which the pitch is randomly changed, and other shapes.

Further, in order to control the light radiation angle from the light emitting element, simultaneously employed may be a light diffusion plate-film. For example, it is possible to employ the diffusion film (LIGHT-UP), produced by Kimoto Co., Ltd.

### <<Applicable Fields to a White Light Emitting Organic EL Element>>

The organic EL element of the present invention may be employed as a type of lamps for lighting or an exposure light source. Further, it may be employed as a display for the type in which still images as well as moving images are directly visible. A driving system, when employed as a display device for reproducing moving images, may be either a simple matrix (a passive matrix) system or an active matrix system.

The white organic electroluminescent element employed in the present invention, if desired, may be subjected to patterning during film making, employing a metal mask or an ink-jet printing method. The electrode and the light emitting layer may be subjected patterning, or all element layers may be subjected to patterning. Light emitting dopants employed in the light emitting layer are not particularly limited. For example, in the case of a backlight in a liquid crystal display element, whiteness will be realized by combining any of those selected from platinum complexes or light emitting dopants known in the art to be suitable for the wavelength region corresponding to CF (color filter) characteristics, or combining light bringing-out and/or light focusing sheets according to the present invention.

The white organic EL element of the present invention is preferred due to the following reasons. It is thereby possible to prepare a full-color organic electroluminescent display of longer operating time at lower driving voltage by obtaining blue light, green light, and red light via a blue filter, a green filter, and a red filter, respectively, employing, as a backlight, white light emitted from the organic electroluminescent element as described in claim 7, by arranging the element and the driving transistor circuit by combining it with a CF (color filter) or matching it to a CF (color filter) pattern.

It is possible to employ the organic EL element of the present invention as display devices, displays, and various light emitting sources. Examples of light emitting sources include home lighting, lighting in vehicles, backlights for clocks and liquid crystals, advertising boards, traffic lights, light sources for optical memory media, light sources for electrophotographic copiers, light sources for optical communication processors, and light sources for optical sensors, but are not limited thereto. Specifically, it is possible to effectively employ it as a backlight for various display devices combined with a color filter, a light diffusing plate, or a light bringing-out film, and light sources for lighting.

### EXAMPLE

Hereafter, the invention will be explained concretely by showing examples. However, the present invention should not be limited these examples.

Further, the structural formulas of compounds used in the examples are shown below. In this connection, although the indication “%” is used in the examples, “%” represents “% by weight” as long as there is no definition in particular.

Further, the structural formulas of compounds used in the examples are shown below.

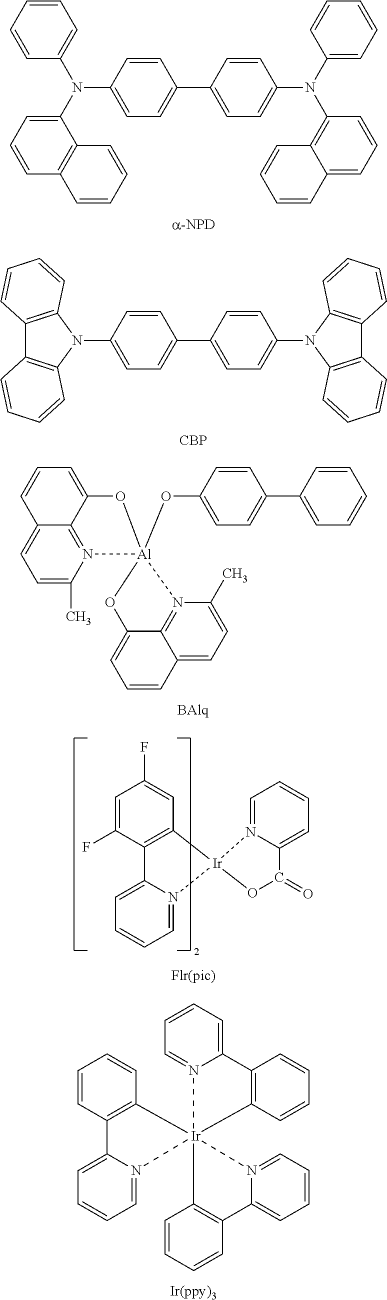

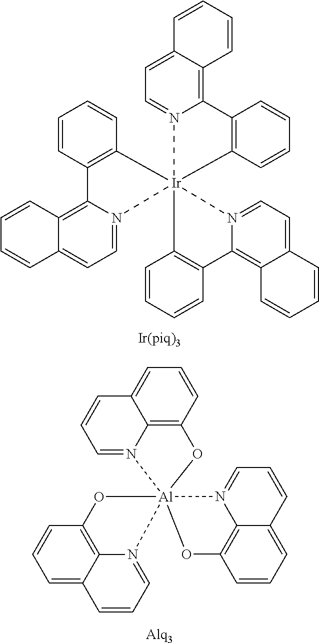

### Example 1

### <<Production of a White Light Emitting Organic Electroluminescent Element 101>>

As an anode, a transparent barrier film with a thickness of about 90 nm was formed on a PEN (polyethylenenaphthalate) substrate with a size of 100 mm×100 mm×0.125 mm by an atmospheric pressure plasma polymerization method. As a result of measurement of a moisture vapor transmission rate by the method based on JIS K-7129B, the transmission rate was 10⁻³ g/m²/day or less. On the formed transparent barrier film, a film of ITO (indium tin oxide) was formed so as to prepare a substrate, and the substrate was subjected to patterning. Thereafter, the substrate provided with the ITO transparent electrode was subjected to ultrasonic cleaning with sopropyl alcohol, dried with dry nitrogen gas, and subjected to UV ozone cleaning for 5 minutes.

### <Positive Hole Injecting Layer>

Poly (3,4-ethylenedioxythiophene)-poly styrene sulfonate was diluted to 70% with purified water, and then the resulting solution was coated to form a film on the above transparent supporting substrate by a spin coating method with a commercially-available spin coater under atmosphere on the condition of 3000 rpm and 30 seconds. Thereafter, the resultant film was dried at 180° C. for 30 minutes, whereby a positive hole injecting layer with a layer thickness of 30 nm was disposed on the substrate.

### <Positive Hole Transporting Layer>

Successively, the above substrate was moved under a nitrogen atmosphere, and on the substrate, a solution in which 20 mg of compound α-NPD was dissolved in 5 ml of toluene was coated to form a film by the spin coating method with the commercially-available spin coater on the condition of 1500 rpm and 30 seconds. Thereafter, the resultant film was dried at 120° C. for 30 minutes. Next, the film was irradiated by a UV lamp with an output of 30 mW/cm² for 30 seconds so as to cause polymerization and cross-linking whereby a positive hole transporting layer with a thickness of 20 nm was disposed on the substrate.

### <Light Emitting Layer A>

Successively, a light emitting layer A coating liquid was prepared as indicated below, and then coated to form a film by the spin coating method with the commercially-available spin coater on the condition of 5000 rpm and 30 seconds, and the resultant film was dried naturally, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### <Light Emitting Layer B>

Successively, a light emitting layer B coating liquid was prepared as indicated below, and then coated to form a film by the spin coating method with the commercially-available spin coater on the condition of 3000 rpm and 30 seconds, and the resultant film was dried at 120° C. for 30 minutes, whereby a light emitting layer B with a thickness of 24 nm was disposed on the substrate.

### (Coating Liquid for a Light Emitting Layer B)

| | | |
|---|---|---|
| PVK (polyvinyl carbazole, molecular weight = | 0.900 | parts by weight |
| 50,000) | | |
| FIr(pic) (blue luminescent dopant) | 0.100 | parts by weight |
| Isopropyl acetate (solvent) | 100 | parts by weights |

### <Electron Transporting Layer>

Successively, an electron transporting layer coating liquid was prepared as indicated below, and then coated to form a film by the spin coating method with the commercially-available spin coater on the condition of 1500 rpm and 30 seconds, and the resultant film was dried at 120° C. for 30 minutes, whereby an electron transporting layer with a thickness of 20 nm was disposed on the substrate.

### (Coating Liquid for an Electron Transporting Layer)

| | | |
|---|---|---|
| ET-A | 0.500 | parts by weight |
| CsF | 0.100 | parts by weight |
| 1-BuOH (solvent) | 100 | parts by weights |

Successively, the substrate on which the layers up to the electron transporting layer were disposed was installed in a vacuum deposition apparatus without atmosphere exposure, and then the inner pressure was reduced to a vacuum of 4×10⁻⁴ Pa. In this connection, a tantalum resistance heating board in which aluminum was filled was installed beforehand in the deposition apparatus.

The resistance heating board in which aluminum was put was energized and heated so as to form a cathode composed of the aluminum with a thickness of 100 nm at a deposition rate of 1 to 2 nm/seconds, whereby a white light emitting organic electroluminescent element 101 was produced.

### <<Production of a White Light Emitting Organic Electroluminescent Element 102>>

The white light emitting organic electroluminescent element 102 was produced in the same way as that in white light emitting organic electroluminescent element 101 except that the light emitting layer A was disposed in the following ways and the light emitting layer B was not disposed.

### <Production of the Light Emitting Layer A in the White Light Emitting Organic Electroluminescent Element 102>

A light emitting layer A coating liquid was prepared as indicated below, and then coated to form a film by the spin coating method with the commercially-available spin coater on the condition of 1600 rpm and 30 seconds, and the resultant film was dried at 120° C. for 30 minutes, whereby a light emitting layer A with a thickness of 40 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### <<Production of a White Light Emitting Organic Electroluminescent Element 103>>

The white light emitting organic electroluminescent element 103 was produced in the same way as that in white light emitting organic electroluminescent element 101 except that the light emitting layer A and the light emitting layer B were formed by a vacuum deposition method.

### <Production of a Light Emitting Layer A and a Light Emitting Layer B in the White Light-Emitting Organic Electroluminescent Element 103>

The substrate on which the layers up to the positive hole transporting layer were disposed was installed in a vacuum deposition apparatus. Ir(ppy)₃, FIr(pic), Ir(piq)₃, CBP, and aluminum were respectively filled in the tantalum resistance heating boards in the vacuum deposition apparatus with respective amounts proper for producing the element. A vapor deposition crucible made of material for molybdenum or tungsten resistance heating was used.

### <Light Emitting Layer A>

Successively, after the inner pressure was reduced to a vacuum of 4×10⁻⁴ Pa, the tantalum resistance heating boards in which 15 parts by weight of Ir(ppy)₃ as a green luminescent dopant, 10 parts by weight of FIr(pic) as a blue luminescent dopant, 4 parts by weight of Ir(piq)₃ as a red luminescent dopant, and CBP as a host were respectively filled, were energized and heated so as to form a light emitting layer A with a thickness of 16 nm on the positive hole transporting layer by co-deposition at a total deposition rate of 0.1 nm/seconds.

### <Light Emitting Layer B>

Successively, the tantalum resistance heating boards in which 10 parts by weight of FIr(pic) as a blue luminescent dopant, and CBP as a host were respectively filled, were energized and heated so as to form a light emitting layer B with a thickness of 24 nm on the light emitting layer A by co-deposition at a total deposition rate of 0.1 nm/seconds.

### <<Production of a White Light Emitting Organic Electroluminescent Element 104>>

The white light emitting organic electroluminescent element 104 was produced in the same way as that in white light emitting organic electroluminescent element 101 except that the light emitting layer A and the light emitting layer B was disposed in the order reverse to the order in white light emitting organic electroluminescent element 101.

### <<Production of a White Light Emitting Organic Electroluminescent Element 105>>

The white light emitting organic electroluminescent element 105 was produced in the same way as that in white light emitting organic electroluminescent element 103 except that the light emitting layer A and the light emitting layer B was deposited in the order reverse to the order in white light emitting organic electroluminescent element 103.

### <<Production of a White Light Emitting Organic Electroluminescent Element 106>>

The white light emitting organic electroluminescent element 106 was produced in the same way as that in white light emitting organic electroluminescent element 101 except that the light emitting layer A was disposed in the following ways.

### <Production of the Light Emitting Layer A in the White Light Emitting Organic Electroluminescent Element 106>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.160 | parts by weight |
| FIr(pic) (blue luminescent dopant) | 0.130 | parts by weight |
| Butyl acetate (solvent) | 100 | parts by weight |

### <<Production of a White Light Emitting Organic Electroluminescent Element 107>>

The white light emitting organic electroluminescent element 107 was produced in the same way as that in white light emitting organic electroluminescent element 101 except that the light emitting layer A was disposed in the following ways.

### <Production of the Light Emitting Layer A in the White Light Emitting Organic Electroluminescent Element 107>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.250 | parts by weight |
| Ir(piq)₃ (red luminescent dopant) | 0.040 | parts by weight |
| Butyl acetate (solvent) | 100 | parts by weight |

### <<Production of a White Light Emitting Organic Electroluminescent Element 108>>

The white light emitting organic electroluminescent element 108 was produced in the same way as that in white light emitting organic electroluminescent element 101 except that the light emitting layer A was disposed in the following ways.

### <Production of the Light Emitting Layer A in the White Light Emitting Organic Electroluminescent Element 108>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| FIr(pic) (blue luminescent dopant) | 0.270 | parts by weight |
| Ir(piq)₃ (red luminescent dopant) | 0.020 | parts by weight |
| Butyl acetate (solvent) | 100 | parts by weight |

### <<Production of a White Light Emitting Organic Electroluminescent Element 109>>

The white light emitting organic electroluminescent element 109 was produced in the same way as that in white light emitting organic electroluminescent element 101 except that the condition of 5000 rpm and 30 seconds of the spin coater in the light emitting layer A was changed to the condition of 4000 rpm and 30 seconds, whereby a light emitting layer A with a thickness of 20 nm was formed, and the condition of 3000 rpm and 30 seconds of the spin coater in the light emitting layer B was changed to the condition of 4000 rpm and 30 seconds, whereby a light emitting layer B with a thickness of 20 nm was formed.

### <<Production of a White Light Emitting Organic Electroluminescent Element 110>>

The white light emitting organic electroluminescent element 110 was produced in the same way as that in white light emitting organic electroluminescent element 101 except that the condition of the spin coater in the light emitting layer A was changed to 4500 rpm and 30 seconds, whereby a light emitting layer A with a thickness of 18 nm was formed, and the condition of the spin coater in the light emitting layer B was changed to 3500 rpm and 30 seconds, whereby a light emitting layer B with a thickness of 22 nm was formed.

### <<Production of a White Light Emitting Organic Electroluminescent Element 111>>

The white light emitting organic electroluminescent element 111 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 111>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 10.5 nm was disposed on the substrate, and next the light emitting layer B coating liquid was coated to form a film by the spin coating method on the condition of 3000 rpm and 30 seconds, whereby a light emitting layer B with a thickness of 29.5 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 150 | parts by weight |

### (Coating Liquid for a Light Emitting Layer B)

| | | |
|---|---|---|
| PVK (polyvinyl carbazole, molecular weight = | 0.920 | parts by weight |
| 50,000) | | |
| FIr(pic) (blue luminescent dopant) | 0.080 | parts by weight |
| Isopropyl acetate (solvent) | 100 | parts by weight |

### <<Production of a White Light Emitting Organic Electroluminescent Element 112>>

The white light emitting organic electroluminescent element 112 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 112>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 9.5 nm was disposed on the substrate, and next the light emitting layer B coating liquid was coated to form a film by the spin coating method on the condition of 3000 rpm and 30 seconds, whereby a light emitting layer B with a thickness of 30.5 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 170 | parts by weight |

### (Coating Liquid for a Light Emitting Layer B)

| | | |
|---|---|---|
| PVK (polyvinyl carbazole, molecular weight = | 0.950 | parts by weight |
| 50,000) | | |
| FIr(pic) (blue luminescent dopant) | 0.050 | parts by weight |
| Isopropyl acetate (solvent) | 100 | parts by weight |

### <<Production of a White Light Emitting Organic Electroluminescent Element 113>>

The white light emitting organic electroluminescent element 113 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 113>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.973 | parts by weight |
| 50,000) | | |
| FIr(pic) (blue luminescent dopant) | 0.027 | parts by weight |
| Isopropyl acetate (solvent) | 100 | parts by weight |

### <<Production of a White Light Emitting Organic Electroluminescent Element 114>>

The white light emitting organic electroluminescent element 114 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 114>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.960 | parts by weight |
| 50,000) | | |
| FIr(pic) (blue luminescent dopant) | 0.040 | parts by weight |
| Isopropyl acetate (solvent) | 100 | parts by weight |

### <<Production of a White Light Emitting Organic Electroluminescent Element 115>>

The white light emitting organic electroluminescent element 115 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 114>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.907 | parts by weight |
| 50,000) | | |
| FIr(pic) (blue luminescent dopant) | 0.093 | parts by weight |
| Isopropyl acetate (solvent) | 100 | parts by weight |

### <<Production of a White Light Emitting Organic Electroluminescent Element 116>>

The white light emitting organic electroluminescent element 115 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 116>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.150 | parts by weight |
| FIr(pic) (blue luminescent dopant) | 0.100 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.880 | parts by weight |
| 50,000) | | |
| FIr(pic) (blue luminescent dopant) | 0.120 | parts by weight |
| Isopropyl acetate (solvent) | 100 | parts by weight |

### <<Production of a White Light Emitting Organic Electroluminescent Element 117>>

The white light emitting organic electroluminescent element 117 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 117>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.810 | parts by weight |
| 50,000) | | |
| Ir(ppy)₃ (green luminescent dopant) | 0.100 | parts by weight |
| FIr(pic) (blue luminescent dopant) | 0.060 | parts by weight |
| Ir(piq)₃ (red luminescent dopant) | 0.030 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.960 | parts by weight |
| 50,000) | | |
| FIr(pic) (blue luminescent dopant) | 0.040 | parts by weight |
| Isopropyl acetate (solvent) | 100 | parts by weight |

### <<Production of a White Light Emitting Organic Electroluminescent Element 118>>

The white light emitting organic electroluminescent element 118 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 118>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coaling liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.790 | parts by weight |
| 50,000) | | |
| Ir(ppy)₃ (green luminescent dopant) | 0.105 | parts by weight |
| FIr(pic) (blue luminescent dopant) | 0.065 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.935 | parts by weight |
| 50,000) | | |
| FIr(pic) (blue luminescent dopant) | 0.065 | parts by weight |
| Isopropyl acetate (solvent) | 100 | parts by weight |

### <<Production of a White Light Emitting Organic Electroluminescent Element 119>>

The white light emitting organic electroluminescent element 118 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 119>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.660 | parts by weight |
| 50,000) | | |
| Ir(ppy)₃ (green luminescent dopant) | 0.160 | parts by weight |
| FIr(pic) (blue luminescent dopant) | 0.120 | parts by weight |
| Ir(piq)₃ (red luminescent dopant) | 0.060 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.880 | parts by weight |
| 50,000) | | |
| FIr(pic) (blue luminescent dopant) | 0.120 | parts by weight |
| Isopropyl acetate (solvent) | 100 | parts by weight |

### <<Production of a White Light Emitting Organic Electroluminescent Element 120>>

The white light emitting organic electroluminescent element 120 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 120>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.640 | parts by weight |
| 50,000) | | |
| Ir(ppy)₃ (green luminescent dopant) | 0.165 | parts by weight |
| FIr(pic) (blue luminescent dopant) | 0.125 | parts by weight |
| Ir(piq)₃ (red luminescent dopant) | 0.070 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.875 | parts by weight |
| 50,000) | | |
| FIr(pic) (blue luminescent dopant) | 0.125 | parts by weight |
| Isopropyl acetate (solvent) | 100 | parts by weight |

### <<Production of a White Light Emitting Organic Electroluminescent Element 121>>

The white light emitting organic electroluminescent element 121 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 121>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 18 nm was disposed on the substrate, and next the light emitting layer B coating liquid was coated to form a film by the spin coating method on the condition of 3000 rpm and 30 seconds, whereby a light emitting layer B with a thickness of 22 nm was disposed on the light emitting layer A.

### (Coating Liquid for a Light Emitting Layer A)

| | | |
|---|---|---|
| PVK (polyvinyl carbazole, molecular weight = | 0.650 | parts by weight |
| 50,000) | | |
| Ir(ppy)₃ (green luminescent dopant) | 0.170 | parts by weight |
| FIr(pic) (blue luminescent dopant) | 0.160 | parts by weight |
| Ir(piq)₃ (red luminescent dopant) | 0.020 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.800 | parts by weight |
| 50,000) | | |
| FIr(pic) (blue luminescent dopant) | 0.200 | parts by weight |
| Isopropyl acetate (solvent) | 100 | parts by weight |

### <<Production of a White Light Emitting Organic Electroluminescent Element 122>>

The white light emitting organic electroluminescent element 121 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 122>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 18 nm was disposed on the substrate, and next the light emitting layer B coating liquid was coated to form a film by the spin coating method on the condition of 3000 rpm and 30 seconds, whereby a light emitting layer B with a thickness of 22 nm was disposed on the light emitting layer A.

### (Coating Liquid for a Light Emitting Layer A)

| | | |
|---|---|---|
| PVK (polyvinyl carbazole, molecular weight = | 0.650 | parts by weight |
| 50,000) | | |
| Ir(ppy)₃ (green luminescent dopant) | 0.170 | parts by weight |
| FIr(pic) (blue luminescent dopant) | 0.160 | parts by weight |
| Ir(piq)₃ (red luminescent dopant) | 0.020 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.790 | parts by weight |
| 50,000) | | |
| FIr(pic) (blue luminescent dopant) | 0.210 | parts by weight |
| Isopropyl acetate (solvent) | 100 | parts by weight |

### <<Production of a White Light Emitting Organic Electroluminescent Element 123>>

The white light emitting organic electroluminescent element 123 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 123>

A light emitting layer A coating liquid and a light emitting layer B coating liquid were prepared as indicated below, first the light emitting layer A coating liquid was coated to form a film by the spin coating method on the condition of 5000 rpm and 30 seconds, whereby a light emitting layer A with a thickness of 16 nm was disposed on the substrate, and next the light emitting layer B coating liquid was coated to form a film by the spin coating method on the condition of 3000 rpm and 30 seconds, whereby a light emitting layer B with a thickness of 24 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.200 | parts by weight |
| FIr(pic) (blue luminescent dopant) | 0.040 | parts by weight |
| Ir(piq)₃ (red luminescent dopant) | 0.050 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.960 | parts by weight |
| 50,000) | | |
| FIr(pic) (blue luminescent dopant) | 0.040 | parts by weight |
| Isopropyl acetate (solvent) | 100 | parts by weight |

### <<Production of a White Light Emitting Organic Electroluminescent Element 124>>

The white light emitting organic electroluminescent element 124 was produced in the same way as that in white light emitting organic electroluminescent element 101 except that the light emitting layer A was disposed in the following ways.

### <Production of the Light Emitting Layer A in the White Light Emitting Organic Electroluminescent Element 124>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.100 | parts by weight |
| FIr(pic) (blue luminescent dopant) | 0.150 | parts by weight |
| Ir(piq)₃ (red luminescent dopant) | 0.040 | parts by weight |
| Butyl acetate (solvent) | 100 | parts by weight |

### <<Production of a White Light Emitting Organic Electroluminescent Element 125>>

The white light emitting organic electroluminescent element 125 was produced in the same way as that in white light emitting organic electroluminescent element 101 except that the light emitting layer A was disposed in the following ways.

### <Production of the Light Emitting Layer A in the White Light Emitting Organic Electroluminescent Element 125>

A light emitting layer A coaling liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.040 | parts by weight |
| FIr(pic) (blue luminescent dopant) | 0.200 | parts by weight |
| Ir(piq)₃ (red luminescent dopant) | 0.050 | parts by weight |
| Butyl acetate (solvent) | 100 | parts by weight |

### <<Production of a White Light Emitting Organic Electroluminescent Element 126>>

The white light emitting organic electroluminescent element 126 was produced in the same way as that in white light emitting organic electroluminescent element 101 except that the light emitting layer A was disposed in the following ways.

### <Production of the Light Emitting Layer A in the White Light Emitting Organic Electroluminescent Element 126>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.650 | parts by weight |
| 50,000) | | |
| Ir(ppy)₃ (green luminescent dopant) | 0.120 | parts by weight |
| FIr(pic) (blue luminescent dopant) | 0.100 | parts by weight |
| Ir(piq)₃ (red luminescent dopant) | 0.130 | parts by weight |
| Butyl acetate (solvent) | 100 | parts by weight |

### <<Production of a White Light Emitting Organic Electroluminescent Element 127>>

The white light emitting organic electroluminescent element 127 was produced in the same way as that in white light emitting organic electroluminescent element 101 except that the light emitting layer A was disposed in the following ways.

### <Production of the Light Emitting Layer A in the White Light Emitting Organic Electroluminescent Element 126>

A light emitting layer A coating liquid was prepared as indicated below, and then coated to form a film by the spin coating method with the commercially-available spin coater on the condition of 5000 rpm and 30 seconds, whereby a light emitting layer A with a thickness of 16 nm was disposed on the substrate.

### (Coating Liquid for a Light Emitting Layer A)

| | | |
|---|---|---|
| PVK (polyvinyl carbazole, molecular weight = | 0.650 | parts by weight |
| 50,000) | | |
| Ir(ppy)₃ (green luminescent dopant) | 0.100 | parts by weight |
| FIr(pic) (blue luminescent dopant) | 0.120 | parts by weight |
| Ir(piq)₃ (red luminescent dopant) | 0.130 | parts by weight |
| Butyl acetate (solvent) | 100 | parts by weight |

### <<Production of a White Light Emitting Organic Electroluminescent Elements 128 to 132>>

The white light emitting organic electroluminescent elements 128 to 132 were produced in the same way as that in white light emitting organic electroluminescent element 101 except that a solvent used for each of the light emitting layer A was changed as shown in Table.

### <<Production of a White Light Emitting Organic Electroluminescent Element 133>>

The white light emitting organic electroluminescent element 133 was produced in the same way as that in white light emitting organic electroluminescent element 101 except that the light emitting layer A and the light emitting layer B were disposed in the following ways.

### <Production of the Light Emitting Layer A and the Light Emitting Layer B in the White Light Emitting Organic Electroluminescent Element 133>

A light emitting layer A coating liquid and a light emitting layer B coating liquid were prepared as indicated below, first the light emitting layer A coating liquid was coated to form a film by the spin coating method on the condition of 4000 rpm and 30 seconds, whereby a light emitting layer A with a thickness of 20 nm was disposed on the substrate, and next the light emitting layer B coating liquid was coated to form a film by the spin coating method on the condition of 4000 rpm and 30 seconds, whereby a light emitting layer B with a thickness of 20 nm was disposed on the light emitting layer A.

### (Coating Liquid for a Light Emitting Layer A)

| | | |
|---|---|---|
| PVK (polyvinyl carbazole, molecular weight = | 0.710 | parts by weight |
| 50,000) | | |
| Ir(ppy)₃ (green luminescent dopant) | 0.100 | parts by weight |
| FIr(pic) (blue luminescent dopant) | 0.150 | parts by weight |
| Ir(piq)₃ (red luminescent dopant) | 0.040 | parts by weight |
| Butyl acetate (solvent) | 100 | parts by weight |

### (Coating Liquid for a Light Emitting Layer B)

| | | |
|---|---|---|
| PVK (polyvinyl carbazole, molecular weight = | 0.950 | parts by weight |
| 50,000) | | |
| FIr(pic) (blue luminescent dopant) | 0.050 | parts by weight |
| Isopropyl acetate (solvent) | 100 | parts by weight |

### <<Sealing>>

The vapor deposition surface side of each of the above-mentioned white light emitting organic electroluminescent elements was covered with epoxy resin, further covered with an aluminum foil with a thickness of 12 μm, and then hardened. The white light emitting organic electroluminescent elements 101 to 133 were produced in a glove box (under the atmosphere of high purity nitrogen gas with a purity of 99.999% or more) under the nitrogen atmosphere without being contact with atmosphere.

### <<Measurement of a Mixing Region>>

Measurement of the mixing region was performed by use of an X-ray photoelectron spectroscopy analyzing apparatuses: AXIS-ULTRA manufactured by Shimadzu Corporation. In this apparatus, each of the white light emitting organic electroluminescent elements was subjected to a depth profile measurement so as to obtain a period of time necessary for measurement from the surface to reach the PEN substrate, a layer thickness of each of the light emitting layer A and the light emitting layer B from the measurement of the signal intensity of iridium contained in the luminescent dopants. The mixing region is defined as a region from a position where the compositions of the light emitting layer B start to exist in the coating layer of the light emitting layer A to a position where the compositions of the light emitting layer A exist in the coating layer of the light emitting layer B. Further, the layer thickness of the light emitting layer A is defined from a middle point of the mixing region in a direction toward the PEN substrate to a point where the signal of iridium is not detected, and the layer thickness of the light emitting layer B is defined from the surface of the light emitting layer B to a middle point of the mixing region.

### <<Evaluation of Organic EL Elements>>

The produced organic EL elements 101 to 133 were subjected to evaluation in the following ways in terms of an external takeoff quantum efficiency, a life span, voltage, and a bending ability.

### (External Takeoff Quantum Efficiency)

The external takeoff quantum efficiency (%) was measured when a constant current of 2.5 mA/cm² was applied at 23° C. under dry nitrogen atmosphere. A spectrum radiance meter CS-1000 (manufactured by Konica Minolta Sensing Corporation) was used for this measurement. An external takeoff quantum efficiency of 15% or more was deemed as acceptance.

### (Service Life (Also Referred to as an “Emission Lifetime”))

When an organic EL element is continuously driven with a constant current to provide the initial luminance of 10000 cds, a time period needed for reducing the luminance by half is measured, and this time period is used a half-life time period (τ0.5) as an index of service life. A spectrum radiance meter CS-1000 (manufactured by Konica Minolta Sensing Corporation) was used for this measurement. A service life of 300 hours or more was deemed as acceptance.

### (Drive Voltage)

Luminance was measured while changing a voltage to be applied to the produced organic EL elements, and a value of the voltage capable of obtaining light emission with a front surface luminance of 1000 cd/m² was calculated by interpolation. A spectrum radiance meter CS-1000 (manufactured by Konica Minolta Sensing Corporation) was used for this measurement. A voltage value of 4.5 V or less was deemed as acceptance.

### (Bending Ability)

One side of the produced white light emitting organic electroluminescent element was held with a clip so as not to cover a light emitting portion. On this condition, the white light emitting organic electroluminescent element was bent by 45 degrees such that the light emitting portion became inside, and successively, it was bent by 45 degrees in the reverse direction. A bending motion to bend the element to the both sides was count as one time, and the bending motion was continued until the organic electroluminescent element did not emit light due to damages or to the maximum number of times of 100. The number of times immediately before the organic electroluminescent element did not emit light was made as the number of time of the bending ability. An organic electroluminescent element be able to emit light even after the number of times of 100 or more was deemed as acceptance.

The evaluation results of Example 1 are shown in Tables 1 to 4.

TABLE 1

| | Light | Light | Layer | | | | Ratio of | | Amount of | Ratio | |
|---|---|---|---|---|---|---|---|---|---|---|---|
| White light | emitting | emitting | thickness | Layer | Thickness | | blue | | dopant | among | |
| emitting | layer | layer | of | thickness | ratio | | dopant | Amount of | in the | dopants | |
| organic | near to | near | the light | of the light | between the | Dopant in | between | dopant in | light | in the | |
| electro- | an | to a | emitting | emitting | light | the light | the light | the light | emitting | light | |
| luminescent | anode | cathode | layer A | layer B | emitting | emitting | emitting | emitting | layer B | emitting | |
| element No. | side | side | (nm) | (nm) | layers B/A | layer A | layers B/A | layer A (%) | (%) | layer A | Remarks |
| 101 | **A | **B | 16.0 | 24.0 | 1.50 | G, B, R | 1.50 | 29.0 | 10.0 | G > B > R | Inventive |
| 102 | **A | | 40.0 | — | — | G, B, R | — | 29.0 | — | G > B > R | Comparative |
| 103 | **A | **B | 16.0 | 24.0 | 1.50 | G, B, R | 1.50 | 29.0 | 10.0 | G > B > R | Comparative |
| 104 | **B | **A | 24.0 | 16.0 | 0.67 | G, B, R | 0.67 | 29.0 | 10.0 | G > B > R | Comparative |
| 105 | **B | **A | 24.0 | 16.0 | 0.67 | G, B, R | 0.67 | 29.0 | 10.0 | G > B > R | Comparative |
| 106 | **A | **B | 16.0 | 24.0 | 1.50 | G, B | 1.15 | 29.0 | 10.0 | G > B | Comparative |
| 107 | **A | **B | 16.0 | 24.0 | 1.50 | G, R | — | 29.0 | 10.0 | G > R | Comparative |
| 108 | **A | **B | 16.0 | 24.0 | 1.50 | B, R | 0.56 | 29.0 | 10.0 | B > R | Comparative |
| 109 | **A | **B | 20.0 | 20.0 | 1.00 | G, B, R | 1.00 | 29.0 | 10.0 | G > B > R | Inventive |
| 110 | **A | **B | 18.0 | 22.0 | 1.20 | G, B, R | 1.20 | 29.0 | 10.0 | G > B > R | Inventive |
| 111 | **A | **B | 10.5 | 29.5 | 2.81 | G, B, R | 2.25 | 29.0 | 8.0 | G > B > R | Inventive |
| 112 | **A | **B | 9.5 | 30.5 | 3.21 | G, B, R | 1.61 | 29.0 | 5.0 | G > B > R | Inventive |
| 113 | **A | **B | 16.0 | 24.0 | 1.50 | G, B, R | 0.41 | 29.0 | 2.7 | G > B > R | Inventive |
| 114 | **A | **B | 16.0 | 24.0 | 1.50 | G, B, R | 0.60 | 29.0 | 4.0 | G > B > R | Inventive |
| 115 | **A | **B | 16.0 | 24.0 | 1.50 | G, B, R | 1.40 | 29.0 | 9.3 | G > B > R | Inventive |
| 116 | **A | **B | 16.0 | 24.0 | 1.50 | G, B, R | 1.80 | 29.0 | 12.0 | G > B > R | Inventive |

**Light emitting layer

TABLE 2

| | Light | Light | Layer | | | | | | Amount of | Ratio | |
|---|---|---|---|---|---|---|---|---|---|---|---|
| White light | emitting | emitting | thickness | Layer | Thickness | | Ratio of | | dopant | among | |
| emitting | layer | layer | of | thickness | ratio | | blue dopant | Amount of | in the | dopants | |
| organic | near to | near | the light | of the light | between | Dopant in | between the | dopant in | light | in the | |
| electro- | an | to a | emitting | emitting | the light | the light | light | the light | emitting | light | |
| luminescent | anode | cathode | layer A | layer B | emitting | emitting | emitting | emitting | layer B | emitting | |
| element No. | side | side | (nm) | (nm) | layers B/A | layer A | layers B/A | layer A (%) | (%) | layer A | Remarks |
| 117 | **A | **B | 16.0 | 24.0 | 1.50 | G, B, R | 1.00 | 19.0 | 4.0 | G > B > R | Inventive |
| 118 | **A | **B | 16.0 | 24.0 | 1.50 | G, B, R | 1.50 | 21.0 | 6.5 | G > B > R | Inventive |
| 119 | **A | **B | 16.0 | 24.0 | 1.50 | G, B, R | 1.50 | 34.0 | 12.0 | G > B > R | Inventive |
| 120 | **A | **B | 16.0 | 24.0 | 1.50 | G, B, R | 1.50 | 36.0 | 12.5 | G > B > R | Inventive |
| 121 | **A | **B | 18.0 | 22.0 | 1.20 | G, B, R | 1.50 | 35.0 | 20.0 | G > B > R | Inventive |
| 122 | **A | **B | 18.0 | 22.0 | 1.20 | G, B, R | 1.58 | 35.0 | 21.0 | G > B > R | Inventive |
| 123 | **A | **B | 16.0 | 24.0 | 1.50 | G, B, R | 1.50 | 29.0 | 4.0 | G > R > B | Inventive |
| 124 | **A | **B | 16.0 | 24.0 | 1.50 | G, B, R | 1.00 | 29.0 | 10.0 | B > G > R | Inventive |
| 125 | **A | **B | 16.0 | 24.0 | 1.50 | G, B, R | 0.75 | 29.0 | 10.0 | B > R > G | Inventive |
| 126 | **A | **B | 16.0 | 24.0 | 1.50 | G, B, R | 1.50 | 35.0 | 10.0 | R > G > B | Comparative |
| 127 | **A | **B | 16.0 | 24.0 | 1.50 | G, B, R | 1.25 | 35.0 | 10.0 | R > B > G | Comparative |
| 128 | **A | **B | 16.0 | 24.0 | 1.50 | G, B, R | 1.50 | 29.0 | 10.0 | G > B > R | Inventive |
| 129 | **A | **B | 16.0 | 24.0 | 1.50 | G, B, R | 1.50 | 29.0 | 10.0 | G > B > R | Inventive |
| 130 | **A | **B | 16.0 | 24.0 | 1.50 | G, B, R | 1.50 | 29.0 | 10.0 | G > B > R | Comparative |
| 131 | **A | **B | 16.0 | 24.0 | 1.50 | G, B, R | 1.50 | 29.0 | 10.0 | G > B > R | Inventive |
| 132 | **A | **B | 16.0 | 24.0 | 1.50 | G, B, R | 1.50 | 29.0 | 10.0 | G > B > R | Inventive |
| 133 | **A | **B | 20.0 | 20.0 | 1.00 | G, B, R | 0.33 | 29.0 | 5.0 | B > G > R | Inventive |

**Light emitting layer

TABLE 3

| White light | | | | | | | |
|---|---|---|---|---|---|---|---|
| emitting | | | | | | | |
| organic | | Kind of a solvent | | | | Mixing | |
| electroluminescent | Difference | Light emitting | SP | | SP | region | |
| element No. | in SP value Δ | layer A | value | Light emitting layer B | value | (nm) | Remarks |
| 101 | 0.1 | Butyl acetate | 8.5 | Isopropyl acetate | 8.4 | 10 | Inv. |
| 102 | 0.1 | Butyl acetate | | | 8.5 | 0 | Comp. |
| 103 | — | — | — | — | — | 0 | Comp. |
| 104 | 0.1 | Butyl acetate | 8.5 | Isopropyl acetate | 8.4 | 9 | Comp. |
| 105 | — | — | — | — | — | 0 | Comp. |
| 106 | 0.1 | Butyl acetate | 8.5 | Isopropyl acetate | 8.4 | 10 | Comp. |
| 107 | 0.1 | Butyl acetate | 8.5 | Isopropyl acetate | 8.4 | 10 | Comp. |
| 108 | 0.1 | Butyl acetate | 8.5 | Isopropyl acetate | 8.4 | 10 | Comp. |
| 109 | 0.1 | Butyl acetate | 8.5 | Isopropyl acetate | 8.4 | 8 | Inv. |
| 110 | 0.1 | Butyl acetate | 8.5 | Isopropyl acetate | 8.4 | 9 | Inv. |
| 111 | 0.1 | Butyl acetate | 8.5 | Isopropyl acetate | 8.4 | 10 | Inv. |
| 112 | 0.1 | Butyl acetate | 8.5 | Isopropyl acetate | 8.4 | 11 | Inv. |
| 113 | 0.1 | Butyl acetate | 8.5 | Isopropyl acetate | 8.4 | 10 | Inv. |
| 114 | 0.1 | Butyl acetate | 8.5 | Isopropyl acetate | 8.4 | 10 | Inv. |
| 115 | 0.1 | Butyl acetate | 8.5 | Isopropyl acetate | 8.4 | 10 | Inv. |
| 116 | 0.1 | Butyl acetate | 8.5 | Isopropyl acetate | 8.4 | 10 | Inv. |
| 117 | 0.1 | Butyl acetate | 8.5 | Isopropyl acetate | 8.4 | 10 | Inv. |
| 118 | 0.1 | Butyl acetate | 8.5 | Isopropyl acetate | 8.4 | 10 | Inv. |
| 119 | 0.1 | Butyl acetate | 8.5 | Isopropyl acetate | 8.4 | 10 | Inv. |
| 120 | 0.1 | Butyl acetate | 8.5 | Isopropyl acetate | 8.4 | 10 | Inv. |
| 121 | 0.1 | Butyl acetate | 8.5 | Isopropyl acetate | 8.4 | 9 | Inv. |
| 122 | 0.1 | Butyl acetate | 8.5 | Isopropyl acetate | 8.4 | 9 | Inv. |
| 123 | 0.1 | Butyl acetate | 8.5 | Isopropyl acetate | 8.4 | 10 | Inv. |
| 124 | 0.1 | Butyl acetate | 8.5 | Isopropyl acetate | 8.4 | 10 | Inv. |
| 125 | 0.1 | Butyl acetate | 8.5 | Isopropyl acetate | 8.4 | 10 | Inv. |
| 126 | 0.1 | Butyl acetate | 8.5 | Isopropyl acetate | 8.4 | 10 | Comp. |
| 127 | 0.1 | Butyl acetate | 8.5 | Isopropyl acetate | 8.4 | 10 | Comp. |
| 128 | 0 | Butyl acetate | 8.5 | Butyl acetate | 8.5 | 25 | Inv. |
| 129 | 0.6 | Butyl acetate | 8.5 | Ethyl acetate | 9.1 | 5 | Inv. |
| 130 | 0.8 | Isobutyl acetate | 8.3 | THF | 9.1 | 0 | Comp. |
| 131 | 0 | Toluene | 8.9 | Toluene | 8.9 | 8 | Inv. |
| 132 | 0 | THF | 9.1 | THF | 9.1 | 12 | Inv. |
| 133 | 0.6 | Butyl acetate | 8.5 | Ethyl acetate | 9.1 | 3 | Inv. |

Inv.: Inventive,
Comp.: Comparative

TABLE 4

| White | | | | | | |
|---|---|---|---|---|---|---|
| light | | | | | | |
| emitting | Performance evaluation | | | | | |
| organic | | | | | Bending | |
| electro- | | External | | | ability | |
| lumi- | light | takeoff | | | (the | |
| nescent | emis- | quantum | Service | | number | |
| element | sion | efficiency | life | Voltage | of | |
| No. | color | (%) | (hours) | (V) | times) | Remarks |
| 101 | White | 17.5 | 413 | 3.85 | >100 | Inventive |
| 102 | White | 12.3 | 405 | 3.96 | >100 | Comparative |
| 103 | White | 17.1 | 411 | 3.88 | 3 | Comparative |
| 104 | White | 7.60 | 189 | 5.83 | >100 | Comparative |
| 105 | White | 6.60 | 272 | 5.74 | 5 | Comparative |
| 106 | White | 14.8 | 154 | 3.74 | >100 | Comparative |
| 107 | White | 13.8 | 385 | 5.75 | >100 | Comparative |
| 108 | White | 14.3 | 354 | 5.87 | >100 | Comparative |
| 109 | White | 16.0 | 351 | 4.03 | >100 | Inventive |
| 110 | White | 17.3 | 409 | 3.87 | >100 | Inventive |
| 111 | White | 15.3 | 370 | 3.80 | >100 | Inventive |
| 112 | White | 15.1 | 308 | 4.40 | >100 | Inventive |
| 113 | White | 15.3 | 318 | 4.20 | >100 | Inventive |
| 114 | White | 16.2 | 378 | 3.84 | >100 | Inventive |
| 115 | White | 17.3 | 408 | 3.87 | >100 | Inventive |
| 116 | White | 15.5 | 318 | 4.26 | >100 | Inventive |
| 117 | White | 15.8 | 311 | 4.38 | >100 | Inventive |
| 118 | White | 16.6 | 380 | 3.88 | >100 | Inventive |
| 119 | White | 17.2 | 410 | 3.85 | >100 | Inventive |
| 120 | White | 15.9 | 350 | 4.10 | >100 | Inventive |
| 121 | White | 17.5 | 397 | 3.95 | >100 | Inventive |
| 122 | White | 15.3 | 399 | 3.97 | >100 | Inventive |
| 123 | White | 15.8 | 328 | 3.86 | >100 | Inventive |
| 124 | White | 16.2 | 347 | 4.02 | >100 | Inventive |
| 125 | White | 16.0 | 340 | 4.10 | >100 | Inventive |
| 126 | Red | 15.1 | 355 | 6.64 | >100 | Comparative |
| 127 | Red | 15.0 | 340 | 6.86 | >100 | Comparative |
| 128 | White | 16.9 | 380 | 3.82 | >100 | Inventive |
| 129 | White | 16.9 | 315 | 3.99 | >100 | Inventive |
| 130 | White | 15.2 | 303 | 4.65 | 8 | Comparative |
| 131 | White | 16.9 | 405 | 3.79 | >100 | Inventive |
| 132 | White | 17.0 | 408 | 3.92 | >100 | Inventive |
| 133 | White | 15.0 | 300 | 4.50 | >100 | Inventive |

AS clear from the results shown in the Tables 1 to 4, it turns out that in the white light emitting organic electroluminescent elements with the structure provided with a mixing region specified in the present invention, an external quantum efficiency and a service life are excellent, a drive voltage is low, and further a bending ability is strong. In particular, the white light emitting organic electroluminescent element No. 101, 110, 115, 119, 121, 131, and 132 exhibit excellent effects.

1-11. (canceled)

12. A white light emitting organic electroluminescence element, comprising:
a resin substrate;
an anode;
a cathode, wherein the anode and the cathode are provided on the resin substrate; and
a light emitting layer A and a light emitting layer B which are provided between the anode and the cathode and contain a light emitting host and a luminescent dopant,
wherein the light emitting layer A contains three or more kinds of luminescent dopants including a red luminescent dopant, a green luminescent dopant, and a blue luminescent dopant, the light emitting layer B contains a blue luminescent dopant, the light emitting layer A and the light emitting layer B neighbor on each other, the light emitting layer A is positioned at a side near to the anode, the light emitting layer B is positioned at a side near to the cathode, and a mixing region is provided between the light emitting layer A and the light emitting layer B.

13. The white light emitting organic electroluminescence element described in claim 12, wherein the mixing region has a thickness made within a range of 10 to 30% of a total thickness of the light emitting layer A and the light emitting layer B.

14. The white light emitting organic electroluminescence element described in claim 12, wherein the light emitting layer B has a layer thickness which is 1.1 to 3.0 times that of the light emitting layer A.

15. The white light emitting organic electroluminescence element described in claim 12, wherein the light emitting layer B has a content of the blue luminescent dopant made within a range of 0.5 to 1.6 times that of the blue luminescent dopant in the light emitting layer A.

16. The white light emitting organic electroluminescence element described in claim 12, wherein the luminescent dopants are contained in the light emitting layer A in a total amount made within a range of 20 to 35 percent by weight to a total solid content in the light emitting layer A.

17. The white light emitting organic electroluminescence element described in claim 12, wherein the luminescent dopants are contained in the light emitting layer B in a total amount made within a range of 7 to 20 percent by weight to a total solid content in the light emitting layer B.

18. The white light emitting organic electroluminescence element described in claim 12, wherein a descending order in a content ratio of each of the red luminescent dopant, the green luminescent dopant, and the blue luminescent dopant which are contained in the light emitting layer A, is made to an order of the green luminescent dopant, the blue luminescent dopant, and the red luminescent dopant.

19. The white light emitting organic electroluminescence element described in claim 12, wherein the light emitting layer A and the light emitting layer B are formed by a wet process with a solvent.

20. The white light emitting organic electroluminescence element described in claim 19, wherein a difference in solubility parameter between respective solvents of the light emitting layer A and the light emitting layer B used in the wet process is 0.5 or less.

21. The white light emitting organic electroluminescence element described in claim 20, wherein each of the respective solvents is an ester compound.

22. The white light emitting organic electroluminescence element described in claim 12, wherein the luminescent dopant is a phosphorescent compound.
